(19) United States
(12) Patent Application Publication
(10) Pub. No.: US 2010/0283072 A1
(43) Pub. Date: Nov. 11, 2010

(54) Quantum dot-based light sheets useful for solid-state lighting

(76) Inventors: Peter T. Kazlas, Sudbury, MA (US); John R. Linton, Concord, MA (US)

Correspondence Address: QD VISION, INC., 313 PLEASANT STREET, 4TH FLOOR, WATERTOWN, MA, 02472, US

(21) Appl. No.: 12/657,282

(22) Filed: Jan. 15, 2010

Related U.S. Application Data
(63) Continuation of application No. PCT/US2008/008822, filed on Jul. 18, 2008.
(60) Provisional application No. 60/950,598, filed on Jul. 18, 2007.
(60) Provisional application No. 60/971,885, filed on Sep. 12, 2007.
(60) Provisional application No. 60/973,644, filed on Sep. 19, 2007.
(60) Provisional application No. 61/016,227, filed on Dec. 21, 2007.

(51) Int. Cl. H01L 33/50

(52) U.S. Cl. 257/98; 977/774; 257/89; 257/E33.061; 257/E33.067

(57) ABSTRACT

A quantum dot-based light sheet or film is disclosed. In certain embodiments, a quantum dot-based light sheet includes one or more films or layers comprising quantum dots (QD) disposed on at least a portion of a surface of a waveguide and one or more with LEDs optically coupled to the waveguide. The film or layer can be continuous or discontinuous. The film or layer can optionally further include a host material in which the quantum dots are dispersed. A solid state light-device including a quantum-dot based sheet or film or optical component disclosed herein is also provided.

This application is a continuation application of commonly owned International Application No. PCT/US2008/008822, filed 18 Jul. 2008, which was published in the English language as PCT Publication No. WO 2009/011922 on 22 Jan. 2009. PCT Application No. PCT/US2008/008822 claims priority to U.S. Application No. 60/950,598, filed 18 Jul. 2007; U.S. Application No. 60/971,885, filed 12 Sep. 2007; U.S. Application No. 60/973,644, filed 19 Sep. 2007; and U.S. Application No. 61/016,227, filed 21 Dec. 2007. Each of the foregoing applications is hereby incorporated herein by reference in its entirety.

### TECHNICAL FIELD OF THE INVENTION

The present invention relates to the technical fields of quantum dot-containing films, quantum dot-containing components useful for lighting applications, and devices including same.

### SUMMARY OF THE INVENTION

In accordance with one embodiment of the present invention, there is provided an optical component comprising an optically transparent substrate including a layer comprising a predetermined arrangement of features on a surface of the substrate, wherein at least a portion of the features comprise a down-conversion material comprising quantum dots.

In certain embodiments, the features are included in a dithered arrangement.

In certain embodiments, features including down-conversion material are arranged in a dithered arrangement, wherein the down-conversion material included in each of the features is selected to include quantum dots capable of emitting light having a predetermined wavelength such that the optical component is capable of emitting light of a preselected color when the component is optically coupled to a light source. In certain embodiments, the optical component is capable of emitting white light. In certain embodiments, such light is a diffuse white light.

In accordance with another aspect of the present invention, there is provided an optical component comprising an optically transparent substrate waveguide including a down-conversion material comprising quantum dots and a solid host material, the down-conversion material being disposed on a predetermined region of a surface of the substrate in a predetermined arrangement, the waveguide being adapted to be optically coupled to a light source.

In accordance with another aspect of the present invention, there is provided an optical component comprising an optically transparent substrate including a down-conversion material comprising quantum dots on a surface of the substrate, wherein the down-conversion material is disposed on the substrate surface in a layered arrangement comprising two or more films. In certain embodiments, each film is capable of emitting light at a wavelength that is distinct from that of any of the other films. In certain embodiments, films are arranged in order of decreasing wavelength from the waveguide surface with the film capable of emitting light at the highest wavelength being closest to the waveguide surface and the film capable of emitting light at the lowest wavelength being farthest from the waveguide surface.

In accordance with another embodiment of the invention, there is provided an optical film comprising a plurality of features comprising down-conversion material in a predetermined arrangement and wherein the down-conversion material included in each of the features is selected to include quantum dots capable of emitting light having a predetermined wavelength such that the optical film is capable of emitting light of a preselected color when optically coupled to a light source. In certain embodiments, the predetermined arrangement comprises a dithered arrangement. In certain embodiments, the preselected color is white.

In accordance with another embodiment of the invention, there is provided an optical film comprising a layered arrangement of two or more films comprising down-conversion material including quantum dots, wherein the down-conversion material included in each film is selected to include quantum dots capable of emitting light having a predetermined wavelength such that the optical film is capable of emitting light of a preselected color when optically coupled to a light source. In certain embodiments, the films are arranged in order of decreasing or increasing wavelength.

In accordance with another embodiment of the invention, there is provided a solid state lighting device comprising an optically transparent substrate including a down-conversion material comprising quantum dots on a surface of the substrate, the substrate being optically coupled to a light source. In certain embodiments, the down-conversion material is disposed on a predetermined region of the substrate surface in a dithered arrangement including features including down-conversion material.

In accordance with another embodiment of the invention, there is provided solid state lighting device comprising a waveguide or other optically transparent substrate including a down-conversion material comprising quantum dots on a surface thereof, the waveguide or component being optically coupled to a light source, wherein the down-conversion material is disposed on the waveguide or component surface in a layered arrangement comprising two or more films. In certain embodiments, each film is capable of emitting light at a wavelength that is distinct from that of any of the other films. In certain embodiments, the films are arranged in order of decreasing wavelength from the waveguide surface with the film capable of emitting light at the highest wavelength being closest to the waveguide surface and the film capable of emitting light at the lowest wavelength being farthest from the waveguide surface.

In accordance with other embodiments of the present invention, there are provided optical components that include any one or more of the optical films described herein.

In accordance with other embodiments of the present invention, there are provided solid state lighting devices that include any one or more of the optical films and/or optical components described herein.

In certain aspects and embodiments of the inventions contemplated by this disclosure, an optically transparent substrate can comprise a waveguide.

In certain aspects and embodiments of the inventions contemplated by this disclosure, an optically transparent substrate can comprise a diffuser.

In certain aspects and embodiments of the inventions contemplated by this disclosure, a substrate can include outcoupling features.

In certain preferred aspects and embodiments of the inventions contemplated by this disclosure, a light source comprises an LED.

The foregoing, and other aspects and embodiments described herein and contemplated by this disclosure all constitute embodiments of the present invention.

It is to be understood that both the foregoing general description and the following detailed description are exemplary and explanatory only and are not restrictive of the invention as claimed. Other embodiments will be apparent to those skilled in the art from consideration of the specification and practice of the invention disclosed herein.

### BRIEF DESCRIPTION OF THE DRAWINGS

In the drawings,

FIG. 1 schematically depicts an example of an embodiment of a quantum dot light sheet comprising an edge-lit LED, a waveguiding diffuser and a quantum dot light enhancement film.

FIG. 2 illustrates a simulated spectra of a CRI=96 QD-based light sheet with a blue 450 nm Phlatlight LED and a QD-LEF containing 4 different QD materials.

FIG. 3 schematically depicts examples of an embodiment of an LED-Luminaire and optically coupled QD-LEF in (a) multi-layer-film and (b) spatially dithered configurations. FIG. 4 schematically depicts an example of an embodiment of a QD-LEF in a back-coupling application.

The attached figures are simplified representations presented for purposes of illustration only; the actual structures may differ in numerous respects, particularly including the relative scale of the articles depicted and aspects thereof.

For a better understanding to the present invention, together with other advantages and capabilities thereof, reference is made to the following disclosure and appended claims in connection with the above-described drawings.

### DETAILED DESCRIPTION OF THE INVENTION

In accordance with one embodiment of the invention, there is provided an optical film comprising a plurality of features comprising down-conversion material in a predetermined arrangement and wherein the down-conversion material included in each of the features is selected to include quantum dots capable of emitting light having a predetermined wavelength such that the optical film is capable of emitting light of a preselected color when optically coupled to a light source. In certain embodiments, the predetermined arrangement comprises a dithered arrangement. In certain embodiments, the preselected color is white.

In accordance with another embodiment of the invention, there is provided an optical film comprising a layered arrangement of two or more films comprising down-conversion material including quantum dots, wherein the down-conversion material included in each film is selected to include quantum dots capable of emitting light having a predetermined wavelength such that the optical film is capable of emitting light of a preselected color when optically coupled to a light source. In certain embodiments, the films are arranged in order of decreasing wavelength from the waveguide surface with the film capable of emitting light at the highest wavelength being closest to the light source and the film capable of emitting light at the lowest wavelength being farthest from the light source.

These films can be included in one or more of the optical components and solid state lighting devices described herein. Preferably, the quantum dots comprise semiconductor nanocrystals. In certain preferred embodiments, such nanocrystals include core-shell structures and include one or more ligands attached to a surface of at least a portion of the nanocrystals.

In accordance with another embodiments of the invention, there is provided an optical component comprising an optically transparent substrate including a layer comprising a predetermined arrangement of features on a surface of the substrate, wherein at least a portion of the features comprise a down-conversion material comprising quantum dots. In certain embodiments, the optically transparent substrate comprises a waveguide. In certain embodiments, the optically transparent substrate comprises a diffuser. In certain embodiments, an upper surface adapted for outcoupling light emitted from the upper surface of the optical component. In certain embodiments, the substrate is adapted for having a light source optically coupled to an edge of the substrate. In certain embodiments, the light source can be embedded in the substrate. In certain embodiments, the substrate is adapted to have light source optically coupled to a surface of the substrate opposite the predetermined arrangement. In certain embodiments, the substrate is adapted to have a light source optically coupled to the surface of the substrate including the predetermined arrangement. In certain embodiments, the substrate is adapted to have a light source optically coupled to the substrate through a prism. In certain embodiments, a light source comprising an LED is preferred.

In certain preferred embodiments, a predetermined arrangement comprises a dithered arrangement.

In certain embodiments, down-conversion material further includes scatterers. In certain embodiments, the scatterers are included in amount in the range from about 0.001 to about 15 weight percent based on the weight of the down-conversion material. In certain embodiments, the scatterers are included in amount in the range from about 0.1 to 2 weight percent based on the weight of the down-conversion material.

In certain embodiments, the predetermined arrangement includes features comprising down-conversion material and features comprising scatterers and/or nonscattering material.

In certain embodiments, the predetermined arrangement includes features comprising down-conversion material and features comprising material with outcoupling and non-scattering capability. Examples of non-scattering materials include clear acrylic, UV curable adhesive, or polycarbonate. Other suitable non-scattering materials are commercially available. In certain embodiments, optically transparent non-scattering material is preferred.

In certain embodiments, the predetermined arrangement comprises features comprising down-conversion material and features comprising reflective material. In certain embodiments, the optical component can further include a layer comprising reflective material. In certain embodiments, a reflective material comprises silver particles. In certain embodiment, a non-specular reflective material can be preferred.

In certain embodiments, the predetermined arrangement comprises features comprising down-conversion material, features comprising reflective material, and features comprising scatterers.

In certain embodiments, scatterers comprise titanium dioxide, barium sulfate, zinc oxide or mixtures thereof. Examples of other scatterers are provided herein.

In certain embodiments, the substrate comprises a waveguide and features comprising down-conversion material can convert the wavelength of at least a portion of a first portion of waveguided light emission from the LED, features comprising scatterers can outcouple a second portion of waveguided light emission from the LED, and features comprising reflective material can recycle at least a portion of light emitted from the waveguide or downconverted light from QDs.

In certain embodiments, the upper surface includes microlenses for outcoupling light.

In certain embodiments, the upper surface includes micro-relief structures for outcoupling light.

In certain embodiments, the predetermined arrangement of features is disposed on a predetermined region of the substrate surface.

In certain embodiments, features comprising down-conversion material are arranged in a dithered arrangement, wherein the down-conversion material included in each of the features is selected to include quantum dots capable of emitting light having a predetermined wavelength such that the optical component is capable of emitting white light when optically coupled to a light source.

In certain embodiments, at least a portion of the features are optically isolated from other features.

In certain embodiments, substantially all of the features are optically isolated from other features.

In certain embodiments, features can be optically isolated from other features by air.

In certain embodiments, features can be optically isolated from other features by a lower or higher refractive index material.

In certain embodiments, down-conversion material further comprises a host material in which the quantum dots are dispersed. In certain embodiments, the down-conversion material includes from about 0.001 to about 15 weight percent quantum dots based on the weight of the host material. In certain embodiments, the down-conversion material includes from about 0.1 to about 5 weight percent quantum dots based on the weight of the host material. In certain embodiments, the down-conversion material includes from about 1 to about 3 weight percent quantum dots based on the weight of the host material. In certain embodiments, the down-conversion material includes from about 2 to about 2.5 weight percent quantum dots based on the weight of the host material. In certain embodiments, the scatterers are further included in the down-conversion material in amount in the range from about 0.001 to about 15 weight percent based on the weight of the host material. In certain embodiments, the scatterers are included in amount in the range from about 0.1 to 2 weight percent based on the weight of the host material. In certain embodiments, a host material comprises a binder. Examples of host materials are provided below.

In certain embodiments, an optical component comprising an optically transparent substrate waveguide including a down-conversion material comprising quantum dots and a solid host material, the down-conversion material being disposed on a predetermined region of a surface of the substrate in a predetermined arrangement, the waveguide being adapted to be optically coupled to a light source.

In certain preferred embodiments, the predetermined arrangement comprises a dithered arrangement.

In certain embodiments, the predetermined arrangement includes features comprising the down-conversion material.

In certain embodiments, at least a portion of the features are configured to have predetermined outcoupling angles. In certain embodiments, at least a portion of the features can include a substantially hemispherical surface. In certain embodiments, at least portion of the features can include a curved surface. In certain embodiments, at least a portion of the features can include prism geometry.

The features can be molded, laser patterned, chemically etched, printed (e.g., but not limited to, by screen-printing, contract printing, or inkjet printing), or formed by other techniques.

In certain embodiments, when it is contemplated that the optical components will have a light source optically coupled to an edge of the substrate, the number of features and closeness of features to each other increases as a function of increasing distance from the light source. In other words, the density of the features on the surface of the optical component is greater as the distance of the features from the lighted edge increases. In such embodiments, light emitted from the optical component can be substantially uniform (e.g., with respect to color and/or brightness) across a predetermined region of the substrate surface.

In certain embodiments, a layer comprising reflective material can be included and positioned in relative to the LED and waveguide or other substrate to reflect light toward the light-emitting surface of the component.

In certain embodiments, a layer comprising reflective material can disposed on a surface of the substrate opposite from the surface including the down-conversion material.

In certain embodiments, the optical component further includes a reflective material on an edge of the substrate opposite from the edge to which the LED is coupled.

In certain embodiments, a reflective material can be included around at least a portion of the edges of the substrate.

In accordance with another embodiment of the present invention, there is provided an optical component comprising an optically transparent substrate including a down-conversion material comprising quantum dots on a surface of the substrate, wherein the down-conversion material is disposed on the substrate surface in a layered arrangement comprising two or more films.

In certain embodiments, the optically transparent substrate comprises a waveguide.

In certain embodiments, the optically transparent substrate comprises a diffuser.

In certain embodiments, the upper surface of the substrate is adapted for outcoupling light emitted from the light emitting surface of the optical component.

In certain embodiments, each film is capable of emitting light at a wavelength that is distinct from that of any of the other films.

In certain embodiments, films are arranged in order of decreasing wavelength from the waveguide surface with the film capable of emitting light at the highest wavelength being closest to the waveguide surface and the film capable of emitting light at the lowest wavelength being farthest from the waveguide surface.

In certain embodiments of an optical component including down-conversion material disposed on the substrate surface in a layered arrangement, the layered arrangement can include a first film including quantum dots capable of emitting blue light, a second film including quantum dots capable of emitting green light, a third film including quantum dots capable of emitting yellow light, and a fourth film including quantum dots capable of emitting red light. In another embodiment of the present invention, such optical component is included in a solid state lighting device including a UV light source capable of being optically coupled to the substrate.

In certain embodiments described herein, an UV light source can comprise an LED capable of emitting 405 nm light. In certain embodiments described herein, an UV light source can comprise a laser capable of emitting 405 nm light. In certain embodiments described herein, an UV light source can comprise an UV cold cathode fluorescent lamp

In certain embodiments of an optical component including down-conversion material disposed on the substrate surface in a layered arrangement, the layered arrangement can include a first film including optically transparent scatterers or non-scattering material, a second film including quantum dots capable of emitting green light, a third film including quantum dots capable of emitting yellow light, and a fourth film including quantum dots capable of emitting red light. In another embodiment of the present invention, such optical component is included in a solid state lighting device including a light source capable of emitting blue light optically coupled to the substrate.

In certain embodiments, a blue light source can comprise an LED capable of emitting 450 or 470 nm light.

In certain embodiments, a blue light source can comprise a laser capable of emitting 450 or 470 nm light.

In certain embodiments of an optical component including down-conversion material disposed on the substrate surface in a layered arrangement, the layered arrangement can include a first film including quantum dots capable of emitting red light, a second film including quantum dots capable of emitting green light, and a third film including quantum dots capable of emitting blue light. In another embodiment of the present invention, such optical component is included in a solid state lighting device including a light source capable of emitting UV light optically coupled to the substrate. Examples of UV light sources include those described above.

In certain embodiments of an optical component including down-conversion material disposed on the substrate surface in a layered arrangement, the layered arrangement can include a first film including quantum dots capable of emitting red light, a second film including quantum dots capable of emitting green light, and a third film including scatterers or non-scattering material to outcouple light. In another embodiment of the present invention, such optical component is included in a solid state lighting device including a light source capable of emitting blue light optically coupled to the substrate. Examples of blue light sources include those described above.

In certain embodiments of an optical component including down-conversion material disposed on the substrate surface in a layered arrangement, the layered arrangement can include a first film including quantum dots capable of emitting blue light, a second film including quantum dots capable of emitting yellow light. In another embodiment of the present invention, such optical component is included in a solid state lighting device including a light source capable of emitting UV light optically coupled to the substrate. Examples of UV light sources include those described above.

In certain embodiments of an optical component including down-conversion material disposed on the substrate surface in a layered arrangement, the layered arrangement can include a first film including quantum dots capable of emitting yellow light, a second film including scatterers or non-scattering material to outcouple light. In another embodiment of the present invention, such optical component is included in a solid state lighting device including a light source capable of emitting blue light optically coupled to the substrate. Examples of blue light sources include those described above.

In certain embodiments of an optical component including down-conversion material disposed on the substrate surface in a layered arrangement, the layered arrangement can include a first film including quantum dots capable of emitting red light, a second film including quantum dots capable of emitting orange light, a third film including quantum dots capable of emitting yellow light, a fourth film including quantum dots capable of emitting green light, and a fifth film including quantum dots capable of emitting blue light. In another embodiment of the present invention, such optical component is included in a solid state lighting device including a light source capable of emitting UV light optically coupled to the substrate. Examples of UV light sources include those described above.

In certain embodiments of an optical component including down-conversion material disposed on the substrate surface in a layered arrangement, the layered arrangement can include a first film including quantum dots capable of emitting red light, a second film including quantum dots capable of emitting orange light, a third film including quantum dots capable of emitting yellow light, a fourth film including quantum dots capable of emitting green light, and a fifth film including scatterers or non-scattering material to outcouple light. In another embodiment of the present invention, such optical component is included in a solid state lighting device including a light source capable of emitting blue light optically coupled to the substrate. Examples of blue light sources include those described above.

In certain embodiments of an optical component including a predetermined arrangement (preferably dithered arrangement) of features including down-conversion material on a substrate, a first portion of the features include quantum dots capable of emitting blue light, a second portion of the features include quantum dots capable of emitting green light, a third portion of the features include quantum dots capable of emitting yellow light, and a fourth portion of the features include quantum dots capable of emitting red light. In another embodiment of the present invention, such optical component is included in a solid state lighting device including a light source capable of emitting UV light optically coupled to the substrate. Examples of UV light sources include those described above.

In certain embodiments of an optical component including a predetermined arrangement (preferably dithered arrangement) of features including down-conversion material on a substrate, a first portion of the features include optically transparent scatterers or non-scattering material, a second portion of the features include quantum dots capable of emitting green light, a third portion of the features include quantum dots capable of emitting yellow light, and a fourth portion of the features include quantum dots capable of emitting red light. In another embodiment of the present invention, such optical component is included in a solid state lighting device including a light source capable of emitting blue light optically coupled to the substrate. Examples of blue light sources include those described above.

In certain embodiments of an optical component including a predetermined arrangement (preferably dithered arrangement) of features including down-conversion material on a substrate, a first portion of the features include quantum dots capable of emitting red light, a second portion of the features include quantum dots capable of emitting green light, and a third portion of the features include quantum dots capable of emitting blue light. In another embodiment of the present invention, such optical component is included in a solid state lighting device including a light source capable of emitting UV light optically coupled to the substrate. Examples of UV light sources include those described above.

In certain embodiments of an optical component including a predetermined arrangement (preferably dithered arrangement) of features including down-conversion material on a substrate, a first portion of the features include optically transparent scatterers or non-scattering material, a second portion of the features include quantum dots capable of emitting red light, and a third portion of the features include quantum dots capable of emitting green light. In another embodiment of the present invention, such optical component is included in a solid state lighting device including a light source capable of emitting blue light optically coupled to the substrate. Examples of blue light sources include those described above.

In certain embodiments of an optical component including a predetermined arrangement (preferably dithered arrangement) of features including down-conversion material on a substrate, a first portion of the features include quantum dots capable of emitting blue light, and a second portion of the features include quantum dots capable of emitting yellow light. In another embodiment of the present invention, such optical component is included in a solid state lighting device including a light source capable of emitting UV light optically coupled to the substrate. Examples of UV light sources include those described above.

In certain embodiments of an optical component including a predetermined arrangement (preferably dithered arrangement) of features including down-conversion material on a substrate, a first portion of the features include optically transparent scatterers or non-scattering material, and a second portion of the features include quantum dots capable of emitting yellow light. In another embodiment of the present invention, such optical component is included in a solid state lighting device including a light source capable of emitting blue light optically coupled to the substrate. Examples of blue light sources include those described above.

In certain embodiments of an optical component including a predetermined arrangement (preferably dithered arrangement) of features including down-conversion material on a substrate, a first portion of the features include quantum dots capable of emitting red light, a second portion of the features include quantum dots capable of emitting orange light, a third portion of the features include quantum dots capable of emitting yellow light, a fourth portion of the features include quantum dots capable of emitting green light, and a fifth portion of the features include quantum dots capable of emitting blue light In another embodiment of the present invention, such optical component is included in a solid state lighting device including a light source capable of emitting UV light optically coupled to the substrate. Examples of UV light sources include those described above.

In certain embodiments of an optical component including a predetermined arrangement (preferably dithered arrangement) of features including down-conversion material on a substrate, a first portion of the features include quantum dots capable of emitting red light, a second portion of the features include quantum dots capable of emitting orange light, a third portion of the features include quantum dots capable of emitting yellow light, a fourth portion of the features include quantum dots capable of emitting green light, and a fifth portion of the features include optically transparent scatterers or non-scattering material. In another embodiment of the present invention, such optical component is included in a solid state lighting device including a light source capable of emitting blue light optically coupled to the substrate. Examples of blue light sources include those described above.

In other embodiments of the invention there are provided solid state lighting devices that include any of the optical components and/or optical films described herein.

In accordance with one embodiment of the present invention, there is provided a solid state lighting device comprising a waveguide including a down-conversion material comprising quantum dots on a surface of the waveguide and a light source capable of being optically coupled to the waveguide. In certain embodiments, the top or upper surface of the waveguide is adapted for outcoupling light. In certain embodiments, the top or upper surface includes microlenses for outcoupling light. In certain embodiments, the top or upper surface includes micro-relief structures for outcoupling light. (A waveguide including a surface adapted from outcoupling light is also referred to elsewhere herein as a waveguide-diffuser.)

In certain embodiments, an outcoupling layer or component is included over the surface of the waveguide that includes the down-conversion material. In certain embodiments, the top or upper surface includes microlenses for outcoupling light. In certain embodiments, the top or upper surface includes micro-relief structures for outcoupling light.

In certain embodiments, down-conversion material further comprises a host material. In certain embodiments, quantum dots are uniformly dispersed in host material. In certain embodiments, host material comprises a binder.

In certain embodiments, a light source comprises an LED. In certain embodiments, a light source comprises a laser. In certain embodiments, a light source comprises a cold cathode compact fluorescent lamp. In certain embodiments, a light source is an UV emitter. In certain embodiments, a light source emits blue light.

In certain embodiments, a light source is capable of being optically coupled to an edge of the waveguide. In certain embodiments, a light source is embedded in the waveguide. In certain embodiments, a light source is capable of being optically coupled to a surface of the waveguide opposite the down-conversion material. In certain embodiments, a light source is capable of being optically coupled to the surface of the waveguide including the down-conversion material. In certain embodiments, a light source is capable of being optically coupled to the waveguide through a prism.

In certain embodiments, scatterers are further included in the device. Scatterers can be included in a layer in the device. In certain embodiments, a layer including scatterers can be disposed over the surface of the waveguide on which the down conversion material is included. In certain embodiments, scatterers can be further included in down-conversion material. In certain embodiments, scatterers are included in features disposed over the waveguide surface.

In certain embodiments, down-conversion material is included in a film disposed on the surface of the waveguide.

In certain embodiments, a film comprises a predetermined arrangement of features comprising down-conversion material. In certain embodiments, a film can include features comprising down-conversion material comprising quantum dots and scatterers. In certain embodiments, a film can further include features comprising scatterers without down-conversion material. In certain embodiments, a film can further include features comprising reflective material. In certain embodiments, a film can further include features comprising reflective non-scattering material.

In certain embodiments, a film comprises a predetermined arrangement of features comprising down-conversion material comprising quantum dots and features comprising reflective material. In certain embodiments, scatterers can also be included in the down-conversion material.

In certain embodiments, a device includes a film comprising a reflective material. An example of a preferred reflective material includes silver particles. Other reflective materials can alternatively be used. In certain embodiments, a film comprising reflective material can be coated in a surface of the waveguide opposite from the surface over which down-conversion material is disposed.

In certain embodiments, a film comprising reflective material is positioned within the device relative to the light source and waveguide to reflect light toward the light-emitting surface of the device.

In certain embodiments, a reflective material can be included on an edge of the waveguide opposite from the edge to which the LED is coupled.

In certain embodiments, a reflective material can be included on a surface of the waveguide opposite from the surface to which the LED is coupled.

In certain embodiments, a reflective material can be disposed around at least a portion of the edges of the waveguide.

In certain embodiments, a solid state lighting device in accordance with the invention includes a predetermined arrangement of features on a surface of a waveguide and a light source capable of being optically coupled to the waveguide, wherein a first portion of the features include down-conversion material, a second portion of the features include scatterers, and a third portion of the features include reflective (preferably non-scattering) materials. In such embodiments, features including down-conversion material can convert the wavelength of at least part of a first portion of waveguided light emission from the light source, features including scatterers can outcouple a first portion of waveguided light emission from the light source, and reflective material can recycle at least a portion of light back into the waveguide. In certain embodiments, the features are arranged in a dithered arrangement. In certain embodiments, features are optically isolated from each other. In certain embodiments, features are optically isolated from each other by air. In certain embodiments, features are optically isolated from each other by lower refractive index material. In certain embodiments, features are optically isolated from each other by higher refractive index material.

In certain embodiments, the down-conversion material is disposed over a predetermined region of the waveguide surface in a dithered arrangement including features comprising down-conversion material. In certain embodiments, such features are arranged in a dithered arrangement. In certain embodiments, at least a portion of the features comprising down-conversion material are optically isolated from other features. In certain embodiments, at least a portion of the features are optically isolated from other features by air. In certain embodiments, at least a portion of the features are optically isolated from other features by a lower refractive index material. In certain embodiments, features including scatterers without down-conversion material are included in the predetermined arrangement.

In certain embodiments including a dithered arrangement of features, the light source is capable of being optically coupled to an edge of the waveguide. In certain embodiments, the density of the features (e.g., the number of features and the closeness of features to each other) is greater as the distance of the features from the light source is longer.

In certain embodiments, the features are configured and arranged to achieve is substantially uniform light emission across a predetermined region of the waveguide surface.

In certain embodiments, a feature is configured to have to have predetermined outcoupling angles.

In certain embodiments, a feature can include a substantially hemispherical surface.

In certain embodiments, a feature can include a curved surface.

In certain embodiments, features can be molded. In certain embodiments, features can be laser patterned. In certain embodiments, features can be chemically etched.

In accordance with another embodiment of the invention, there is provided a solid state lighting device comprising a waveguide including one or more down-conversion materials comprising quantum dots on a surface of the waveguide and a light source capable of being optically coupled to the waveguide, wherein the one or more down-conversion materials are disposed on the waveguide surface as separate layers. In certain embodiments, each layer including down-conversion material is capable of emitting light at a wavelength that is distinct from that of other layers including down-conversion material. In certain embodiments, layers including down-conversion material are arranged in order of decreasing wavelength from the waveguide surface. For example, a layer including down-conversion material including quantum dots capable of emitting light at the highest wavelength is disposed closest to the waveguide surface and a layer including down-conversion material including quantum dots capable of emitting light at the lowest wavelength of the layered arrangement is disposed farthest from the waveguide surface.

In certain embodiments, including a UV emitting light source, a layered arrangement including down-conversion materials includes a first layer including quantum dots capable of emitting blue light, a second layer including quantum dots capable of emitting green light, a third layer including quantum dots capable of emitting yellow light, and a fourth layer including quantum dots capable of emitting red light. In certain embodiments, a light source comprises an LED capable of emitting UV light with a 405 nm wavelength. In certain embodiments, a light source comprises a laser capable of emitting UV light with a 405 nm wavelength. In certain embodiments, a light source comprises an UV cold cathode fluorescent lamp.

In certain embodiments including a light source capable of emitting UV light, an UV filter can be further included to remove UV light from light emitted from the device.

In certain embodiments, including a blue emitting light source, a layered arrangement including down-conversion materials includes a first layer including scatterers, a second layer including quantum dots capable of emitting green light, a third layer including quantum dots capable of emitting red light. In certain embodiments, a light source comprises an LED capable of emitting blue light with a 450 nm wavelength.

In certain embodiments, other predetermined layered or dithered arrangements of down-conversion materials having preselected light emitting capabilities can be used to achieve a predetermined light output.

In embodiments of the inventions described herein which utilize an UV light source, an UV filter can further be included to remove UV light from light emitted from the device.

In certain embodiments of the inventions described herein including layers or films of down-conversion material, the thickness can from about 0.1 to about 200 microns. In certain embodiments, the thickness is, less than 100 microns, less than 50 microns, less than 20 microns, etc. A preferred film thickness is from about 10 to about 20 microns.

In certain embodiments, an optical film is laminated onto the optical substrate,

In certain embodiments, a flexible or conformable light source can be used.

In certain embodiments, an optical film can be prepared on a release substrate and transferred to the optical substrate.

In certain embodiments, a protective environmental coating may also be applied to the emitting face to protect the QD film from the environment. Preferable this layer would be of low refractive index and would include outcoupling structures such as microlenses.

As discussed above, one embodiment of the present invention relates to a quantum dot-based light sheet which includes one or more films or layers comprising a down conversion material including quantum dots (QD) disposed on at least a portion of a surface of a waveguide and one or more with LEDs optically coupled to the waveguide. The film or layer can be continuous or discontinuous. The down-conversion material included in the film or layer can optionally further include a host material in which the quantum dots are dispersed.

In certain embodiments, a quantum dot-based light sheet can further include scatterers. In certain embodiments, the scatterers can be included in down-conversion material. In certain embodiments, the scatterers can be included in a separate layer. In certain embodiments, a film or layer including a down-conversion material can be disposed in a predetermined arrangement including features wherein a portion of the features include scatterers but do not include down-conversion material. In such embodiments, the features including down-conversion material can optionally also include scatterers.

Examples of scatterers (also referred to as light scattering particles) that can be used in the embodiments and aspects of the inventions contemplated by this disclosure, include, without limitation, metal or metal oxide particles, air bubbles, and glass and polymeric beads (solid or hollow). Other scatterers can be readily identified by those of ordinary skill in the art. In certain embodiments, scatterers have a spherical shape. Preferred examples of scattering particles include, but are not limited to, TiO₂, SiO₂, BaTiO₃, BaSO₄, and ZnO. Particles of other materials that are non-reactive with the host material and that can increase the absorption pathlength of the excitation light in the host material can be used. Additionally, scatterers that aid in the out-coupling of the down-converted light may be used. These may or may not be the same scatterers used for increasing the absorption pathlength. In certain embodiments, the scatterers may have a high index of refraction (e.g., TiO₂, BaSO₄, etc) or a low index of refraction (gas bubbles). Preferably the scatterers are not luminescent.

Selection of the size and size distribution of the scatterers is readily determinable by those of ordinary skill in the art. The size and size distribution is preferably based upon the refractive index mismatch of the scattering particle and the host material in which it the scatterer is to be dispersed, and the preselected wavelength(s) to be scattered according to Rayleigh scattering theory. The surface of the scattering particle may further be treated to improve dispersability and stability in the host material. In one embodiment, the scattering particle comprises TiO₂ (R902+ from DuPont) of 0.2 μm particle size, in a concentration in a range from about 0.001 to about 20% by weight. In certain preferred embodiments, the concentration range of the scatterers is between 0.1% and 10% by weight. In certain more preferred embodiments, a composition includes a scatterer (preferably comprising TiO₂) at a concentration in a range from about 0.1% to about 5% by weight, and most preferably from about 0.3% to about 3% by weight.

Examples of a host material useful in various embodiments and aspect of the inventions described herein include polymers, monomers, resins, binders, glasses, metal oxides, and other nonpolymeric materials. In certain embodiments, an additive capable of dissipating charge is further included in the host material. In certain embodiments, the charge dissipating additive is included in an amount effective to dissipate any trapped charge. In certain embodiments, the host material is non-photoconductive and further includes an additive capable of dissipating charge, wherein the additive is included in an amount effective to dissipate any trapped charge. Preferred host materials include polymeric and non-polymeric materials that are at least partially transparent, and preferably fully transparent, to preselected wavelengths of visible and non-visible light. In certain embodiments, the preselected wavelengths can include wavelengths of light in the visible (e.g., 400-700 nm), ultraviolet (e.g., 10-400 nm), and/or infrared (e.g., 700 nm-12 μm) regions of the electromagnetic spectrum. Preferred host materials include cross-linked polymers and solvent-cast polymers. Examples of preferred host materials include, but are not limited to, glass or a transparent resin. In particular, a resin such as a non-curable resin, heat-curable resin, or photocurable resin is suitably used from the viewpoint of processability. As specific examples of such a resin, in the form of either an oligomer or a polymer, a melamine resin, a phenol resin, an alkyl resin, an epoxy resin, a polyurethane resin, a maleic resin, a polyamide resin, polymethyl methacrylate, polyacrylate, polycarbonate, polyvinyl alcohol, polyvinylpyrrolidone, hydroxyethylcellulose, carboxymethylcellulose, copolymers containing monomers forming these resins, and the like. Other suitable host materials can be identified by persons of ordinary skill in the relevant art. Preferably a host material is not a metal.

In certain embodiments, a host material comprises a photocurable resin. A photocurable resin may be a preferred host material in certain embodiments in which the composition is to be patterned. As a photo-curable resin, a photo-polymerizable resin such as an acrylic acid or methacrylic acid based resin containing a reactive vinyl group, a photo-crosslinkable resin which generally contains a photo-sensitizer, such as polyvinyl cinnamate, benzophenone, or the like may be used. A heat-curable resin may be used when the photo-sensitizer is not used. These resins may be used individually or in combination of two or more.

In certain embodiments, a host material comprises a solvent-cast resin. A polymer such as a polyurethane resin, a maleic resin, a polyamide resin, polymethyl methacrylate, polyacrylate, polycarbonate, polyvinyl alcohol, polyvinylpyrrolidone, hydroxyethylcellulose, carboxymethylcellulose, copolymers containing monomers forming these resins, and the like can be dissolved in solvents known to those skilled in the art. Upon evaporation of the solvent, the resin forms a solid host material for the semiconductor nanoparticles. In certain embodiments, the composition including quantum confined semiconductor nanoparticles and a host material can be formed from an ink composition comprising quantum confined semiconductor nanoparticles and a liquid vehicle, wherein the liquid vehicle comprises a composition including one or more functional groups that are capable of being cross-linked. The functional units can be cross-linked, for example, by UV treatment, thermal treatment, or another cross-linking technique readily ascertainable by a person of ordinary skill in a relevant art. In certain embodiments, the composition including one or more functional groups that are capable of being cross-linked can be the liquid vehicle itself. In certain embodiments, it can be a co-solvent. In certain embodiments, it can be a component of a mixture with the liquid vehicle. In certain embodiments, the ink can further include scatterers.

In certain embodiments, quantum dots (e.g., semiconductor nanocrystals) are distributed within the host material as individual particles. Preferably the quantum dots are well-dispersed in the host material.

In certain embodiments, outcoupling members or structures may also be included. In certain embodiments, they can be distributed across a surface of the waveguide or down-conversion material. In certain preferred embodiments, such distribution is uniform or substantially uniform. In certain embodiments, coupling members or structures may vary in shape, size, and/or frequency in order to achieve a more uniform light distribution. In certain embodiments, coupling members or structures may be positive, i.e., sitting above the surface of the waveguide, or negative, i.e., depressed into the surface of the waveguide, or a combination of both. In certain embodiments, one or more features comprising a composition including a host material and quantum confined semiconductor nanoparticles can be applied to a surface of a positive coupling member or structure and/or within a negative coupling member or structure.

In certain embodiments, coupling members or structures can be formed by molding, embossing, lamination, applying a curable formulation (formed, for example, by techniques including, but not limited to, spraying, lithography, printing (screen, inkjet, flexography, etc), etc.)

In certain embodiments, an LED comprises a blue-emitting PhlatLight LED, to produce both light output with improved color rendering and improved luminaire efficiency. Preferably the light has Color Rendering Index is of at least about 90. Preferably, luminaire efficiency is at least about 50 lm/W. (A quantum dot-based light sheet is also referred to herein as a quantum dot light sheet or QDLS.)

In certain embodiments, one or more efficiently edge-coupled collimated, high efficiency blue Phlatlight LEDs is coupled to a waveguide to diffuse the light.

In certain embodiments, the waveguide is flat. In certain embodiments, commercially available waveguides can be used. In certain embodiments, commercially available diffusers can be used. In certain embodiments, commercially available waveguide-diffusers can be used.

In certain preferred embodiments, the waveguide and/or diffuser is transparent to light coupled to the waveguide component from a light source and to light emitted by the quantum dots.

In certain embodiments, the waveguide and/or diffuser can comprise a rigid material, e.g., glass, polycarbonate, acrylic, quartz, sapphire, or other known rigid materials with waveguide component characteristics.

In certain embodiments, the waveguide and/or diffuser can alternatively comprise a flexible material, e.g., a polymeric material such as plastic or silicone (e.g. but not limited to thin acrylic, epoxy, polycarbonate, PEN, PET, PE).

In certain embodiments, the waveguide and/or diffuser is planar.

In certain embodiments, the surface of the waveguide and/or diffuser from which light is emitted is selected to enhance or otherwise alter the pattern, angle, or other feature of light transmitted therethrough. For example, in certain embodiments, the surface may be smooth; in certain embodiments, the surface may be non-smooth (e.g., the surface is roughened or the surface includes one or more raised and/or depressed features); in certain embodiments, the surface may include both smooth and non-smooth regions.

In certain embodiments, the QDLS further includes LED-diffuser packaging.

In certain embodiments, the QDLS further includes features to redirect of dissipate thermal output of the device.

In certain preferred embodiments, the quantum dots comprise quantum dots capable of emitting light of a predetermined wavelength. In certain embodiments, the quantum dots include two or more different quantum dots, each of which is capable of emitting light of a predetermined color that is distinct from that emitted by the other different quantum dots. Preferably, the quantum dots have a high quantum yield (e.g., at least 50%, at least 60%, at least 70%, at least 80%, or at least 90%).

In certain embodiments, the QDLS further includes an outcoupling film.

In certain embodiments, the QDLS includes a multi-layer down conversion outcoupling film.

In certain embodiments, the QDLS is RoHS compliant.

In certain embodiments, the QDLS includes a composite down-conversion diffuser waveguide that includes a light enhancement film comprising quantum dots (QD-LEFs).

In certain embodiments, a QDLS in accordance with the invention is capable of emitting white light and has a luminaire efficiency of at least 50 lm/W, a CRI of at least 90. In certain embodiments, the color stability of the light emitted by the sheet including quantum dots is not dependent on LED input flux.

In certain embodiments, a QDLS including large-emitting area quantum dot (QD) light sheets (QDLS) with highly efficient and stable color rendering index (CRI) can be used for task lighting applications.

In certain embodiments, a QDLS design will involve edge-coupling Luminus Devices' high efficiency blue Phlatlight LEDs into commercially available waveguiding diffusers that have been coated with quantum dot light enhancement films (QD-LEF) for efficient and stable color conversion. This design is expected to generate high efficiency, CRI=90 white light with unprecedented color stability performance over a wide range of intensities.

Preferably, quantum dots are prepared by colloidal synthesis. Most preferably, the surfaces of the quantum dots include surface capping ligands that are compatible with the material included in the sheet to form a down-conversion film. Such material compatibility will provide the a stable and efficient QD down-conversion film. In certain embodiments, the material included in the sheet comprises an organic polymer host material.

In certain embodiments, a quantum dot will comprise a core-shell structure. Preferably, the shell will comprise a thick (e.g., but not limited to, greater than 2 monolayers, greater than 5 monolayers, greater than 7 monolayers, greater than 10 monolayers), graded, uniform alloy layer disposed on at least a portion of a surface of the core. Such core-shell structure will improve the stability and efficiency of emission. Most preferably, quantum dots included in a quantum-dot down conversion film comprise core-shell QD materials capable of emitting light at the selected wavelengths for narrow size distributions and high quantum yield (QY).

In certain embodiments, a quantum dot down conversion film will be included in a QDLS by a solution-based deposition technique.

In certain embodiments, the quantum dot down conversion film includes a host matrix selected to maintain the quantum yield (QY) of the dots in solid state, to achieving high CRI and light extraction efficiency as well as providing a stable, long life environment for the dots in a SSL application. In certain embodiments, each QD down-conversion layer can be the same or different.

In certain preferred embodiments, a QDLS includes an LED, a sheet or film including one or more different quantum dots, and a waveguide and/or diffuser suitable for QD light enhancement to achieve high CRI. In certain embodiments, the LED comprises a Phlatlight available from Luminus Devices. A diffuser will be selected based on its color, power efficiency, brightness, cost, and form factor. A particularly desirable LED-diffuser coupled assembly will minimize insertion losses between the LED luminaire and diffuser as well as the diffuser and QD-LEF, with special emphasis on mitigating reabsorption.

Preferably, the QDLS components will be selected and configured, in order that the component interactions, including improving LED-diffuser and DCM-diffuser coupling optics in conjunction with minimizing reabsorption to realize maximum module efficiency and CRI versus current and lifetime as well as reduced module cost.

In certain embodiments, an LED and driver assembly will have an LED wall plug efficiency of at least 20% and more preferably, at least 30%.

In certain embodiments, an LED will have a peak wavelength of 450 nm.

In certain embodiments, an LED will have a FWHM of 20 nm or less.

In certain embodiments, an LED driver assembly will have a driver efficiency of at least 85% and more preferably at least 90%.

In certain embodiments, an LED comprises a Phlatlight available from Luminus Devices.

In certain embodiments including a diffuser, the LED coupling efficiency will be at least 60%, and more preferably, at least 75%.

In certain embodiments, a one or more coupling members or structures can be included that permit at least a portion of light emitted from a light source to be optically coupled from the light source into the diffuser and/or waveguide. Such members or structures include, for example, and without limitation, members or structures that are attached to a surface of the diffuser and/or waveguide, protrude from a surface of the diffuser and/or waveguide (e.g., prisms, gratings, etc.), are at least partially embedded in the waveguide and/or diffuser, or are positioned at least partially within a cavity in the waveguide and/or diffuser.

In certain embodiments including a diffuser, the diffuser will have a diffuser transmission efficiency of at least 70%, and preferably, at least 80%.

In certain embodiments, the QD light enhancement film will have a down conversion efficiency of at least 60%, and preferably, at least 70%.

In certain embodiments of a QDLS, the luminous efficacy of radiation (lumens/watt) will be at least about 330, and preferably at least about 400.

In certain embodiments of a QDLS in accordance with the invention, the QDLS is capable of producing light with a CRI of at least 85%, and more preferably, at least 90%.

In certain embodiments of a QDLS in accordance with the invention, the QDLS is capable of producing light with a color temperature (CCT) of 5500K.

In certain embodiments of a QDLS in accordance with the invention, the total lumen output will be at least 294, and preferably, at least 504.

In certain embodiments of a QDLS in accordance with the invention, the luminaire efficiency will be at least 42%, and preferably, at least 60%.

In certain embodiments of a QDLS in accordance with the invention, the total system efficacy (lm/W) will be at least 17, and preferably, at least 50.

Examples of dimensions of one embodiment of a QDLS include, without limitation, an area of 10 cm×30 cm and a thickness of 10 mm.

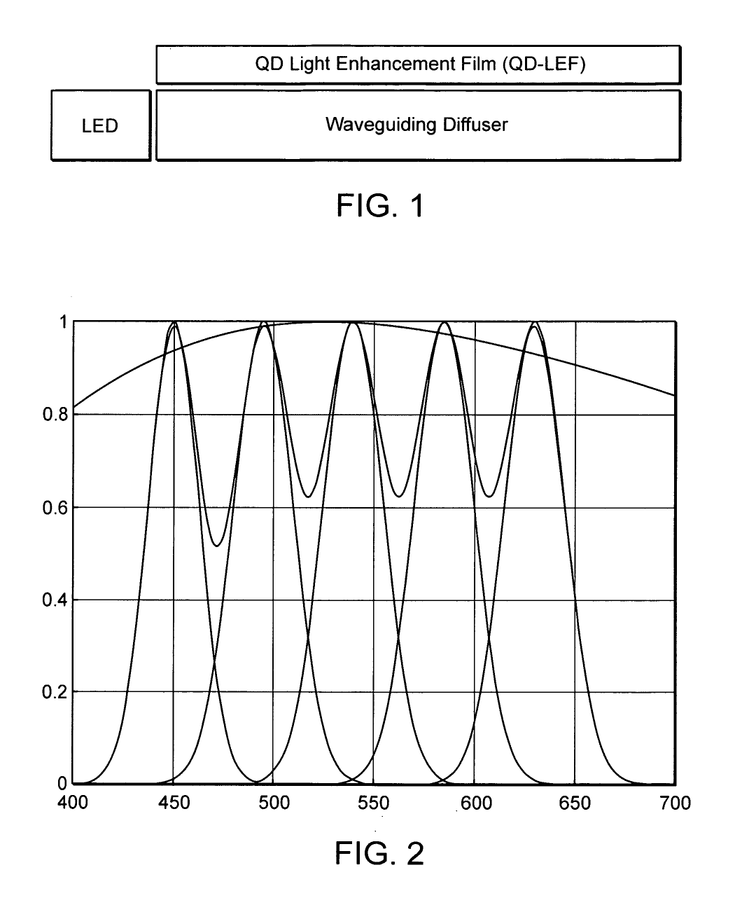

A schematic of an example of embodiment of a QDLS of the invention is provided in FIG. 1. FIG. 1 depicts a quantum dot light sheet (QDLS) comprising an edge-lit LED, a waveguiding diffuser and a quantum dot light enhancement film (QD-LEF). The waveguide component may also have minimal or no additional diffusing properties outside of basic waveguiding, relying only on the QD enhancement film to outcouple the light. The non-emitting faces of the waveguide may be coated with additional reflective surfaces to improve outcoupling.

A QDLS of the invention will be useful for solid state lighting applications. In certain embodiments, a QDLS in accordance with the invention is suitable for use in large area, high efficiency lighting applications. In certain embodiments, a QDLS in accordance with the invention can provide stable color rendering index (CRI) which can be desirable, for example, and without limitation, for task lighting applications.

In certain embodiments, a QDLS will include edge-coupling an LED into commercially available waveguiding diffusers that have been coated with one or more layers or films including quantum dots for efficient and stable color conversion (see, for example, FIG. 1). (A layer or film including quantum dots is also referred to herein as a “quantum dot light enhancement film” or QD-LEF.) As shown in FIG. 2 the present invention has the potential to generate CRI>95 white light with unprecedented color stability performance over a wide range of intensities.

FIG. 2 illustrates a simulated spectra of a CRI=96 QD-based light sheet with a blue 450 nm Phlatlight LED and a QD-LEF containing 4 different QD materials. A 5500K black body radiation curve is also plotted for reference.

The unique aspect of the invention includes the combination of (a) a efficient LED technology as a high power light source with (b) simple, cost-effective solution processable techniques for generating QD-LEFs that will ultimately produce (c) a complete LED luminaire that can achieve efficient, stable, and high CRI white light.

Since the first phosphor-converted (pc) white LED was introduced in the mid-1990s (S. Nakamura, T. Mukai, and M. Senoh, Appl. Phys. Lett. 1994, 64, 1687), pc-LEDs have become a common LED-based white light source. While this technique is inherently less efficient than mixing red, green, and blue (RGB) light from an LED array, it can provide distinct advantages in the areas of color rendering and stability. The use of down-converting materials allows for higher quality “white” by emitting light that more closely matches a black body radiation profile. Furthermore, pc-LEDs provide a much simpler device platform since one highly efficient source LED can be used with one or multiple color converting materials. In the case of the RGB color mixing, the LED array requires active feedback control in order to stabilize the color profile due to the fact that individual LEDs typically exhibit vastly different dependencies with respect to temperature, drive current, and device lifetime.

Despite these advantages, the luminous efficacy of pc-LEDs must improve significantly if they are to become useful in general lighting applications. Efficiency enhancements have been achieved in multiple areas, including the internal quantum efficiency of the source LEDs (M. R. Krames et al., Phys. Stat. Sol. A 2002, 192, 237; T. Onuma et al., J. Appl. Phys. 2004, 95, 2495; C. Wetzel, T. Salagaj, T. Detchprohm, P. Li, and J. S. Nelson, Appl. Phys. Lett. 2004, 85, 866.), phosphor-conversion efficiency (J. K. Park, C. H. Kim, S. H. Park, H. D. Park, and S. Y. Choi, Appl. Phys. Lett. 2004, 84, 1647; R. Mueller-Mach, G. O. Mueller, and M. R. Krames, Proc. SPIE 2004, 5187, 115; C. J. Summers, B. Wagner, and H. Menkara, Proc. SPIE 2004, 5187, 123; N. Taskar, R. Bhargava, J. Barone, V. Chhabra, V. Chabra, D. Dorman, A. Ekimov, S. Herko, and B. Kulkarni, Proc. SPIE 2004, 5187, 133; A. A. Setlur, A. M. Srivastava, H. A. Comanzo, G. Chandran, H. Aiyer, M. V. Shankar, and S. E. Weaver, Proc. SPIE 2004, 5187, 142; S. G. Thoma, B. L. Abrams, L. S. Rohwer, A. Sanchez, J. P. Wilcoxon, and S. M. Woessner, Proc. SPIE 2004, 5276, 202), and the extraction efficiency associated with the LED luminaire (N. Narendran, Y. Gu, J. P. Freyssinier-Nova, and Y. Zhu, Phys. Stat. Sol. A 2005, 202, R60; T. N. Oder, K. H. Kim, J. Y. Lin, and H. X. Jiang, Appl. Phys. Lett. 2004, 84, 466; H. W. Choi, M. D. Dawson, P. R. Edwards, and R. W. Martin, Appl. Phys. Lett. 2003, 83, 4483; J. J. Wierer, M. R. Krames, J. E. Epler, N. F. Gardner, M. G. Craford, J. R. Wendt, J. A. Simmons, and M. M. Sigalas, Appl. Phys. Lett. 2004, 84, 3885; M. R. Krames et al., Appl. Phys. Lett. 1999, 75, 2365; T. Fujii, Y. Gao, R. Sharma, E. L. Hu, S. P. DenBaars, and S. Nakamura, Appl. Phys. Lett. 2004, 84, 855; T. Gessmann, E. F. Schubert, J. W. Graff, K. Streubel, and C. Karnutsch, IEEE Electron. Device Lett. 2003, 24, 683. The research in the area of LED luminaires has focused on methods to improve photon extraction that are localized to the LED module. For example, roughening the surface (T. Fujii, Y. Gao, R. Sharma, E. L. Hu, S. P. DenBaars, and S. Nakamura, Appl. Phys. Lett. 2004, 84, 855) or introducing a photonic crystal (T. N. Oder, K. H. Kim, J. Y. Lin, and H. X. Jiang, Appl. Phys. Lett. 2004, 84, 466; H. W. Choi, M. D. Dawson, P. R. Edwards, and R. W. Martin, Appl. Phys. Lett. 2003, 83, 4483; J. J. Wierer, M. R. Krames, J. E. Epler, N. F. Gardner, M. G. Craford, J. R. Wendt, J. A. Simmons, and M. M. Sigalas, Appl. Phys. Lett. 2004, 84, 3885) on the LED die can increase extraction efficiencies by 100% or more. While these methods increase the light out-coupling directly from the LED, they are unable to enhance the light emitted from the phosphor conversion materials. More than half of the converted light can be back-scattered by the phosphor into the LED package (K. Yamada, Y. Imai, and K. Ishii, J. Light Vis. Environ. 2003, 27, 70). Work has been done to extract the scattered light by moving the phosphor layer away from the die, realizing a 60% enhancement in the luminous efficiency (N. Narendran, Y. Gu, J. P. Freyssinier-Nova, and Y. Zhu, Phys. Stat. Sol. A 2005, 202, R60). This particular method suffered from spatial color variations but had the additional benefit of improved thermal management and potential increase in source life since the phosphor is removed from the die.

A QDLS in accordance with the invention represents an advance over the pc-LEDs noted above. In certain embodiments, quantum dots are distributed in an edge-coupled waveguide LED luminaire to harness the tunable emission and excellent color rendering of QDs. This innovative solution will improve thermal management of the system by removing the conversion material from the LED source resulting in stable color rendering that is independent of source power output. Predetermined geometry and orientation of the QD conversion materials within the waveguide as well as methods for ensuring efficient extraction of scattered light within the luminaire can be utilized. In certain embodiments, superior color rendering and stability with system power efficiencies exceeding 50 lm/W are expected.

As discussed above, in certain embodiments an LED for use in the present invention comprises a high brightness suitable for edge coupling such as a photonic lattice-based PhlatLight™ LED available from Luminus Devices. The photonic lattice permits scaleable light extraction from the LED chip, meaning that very large PhlatLight LEDs can be made without sacrificing performance. The photonic lattice is also designed to extract light directly into air—eliminating the need for encapsulation, one of the main causes of poor LED reliability, especially during high power operation.

In certain embodiments, a device includes one or more down-conversion films including quantum dots and one or high-power LEDs suitable for edge coupling that are configured to minimize self-absorption of light emitted by the quantum dots included in the down-conversion films. In certain preferred embodiments, the QDLS of the invention is ROHS compliant.

In certain embodiments, a down-conversion material includes quantum dots dispersed in a host material, wherein the quantum dots, prior to being included in the host material, have a quantum efficiency up to >85%. In certain embodiments, a down conversion material comprising a host material including QD dispersed therein has a quantum efficiency over 50% in the solid state. In certain embodiments, at least a portion of the quantum dots include one or more ligands attached to a surface thereof that are chemically compatibility with a host material. To maintain high quantum efficiency of QDs, it is preferred to attach capping ligands to quantum dots that are compatible with the chemical nature of the host material, be that an organic or inorganic material. The transition from a liquid to a solid dispersion can affect QD efficiencies. It is believed that the speed of this transition is important to maintaining high quantum efficiency, as the rate competition “locks” the QDs into place before aggregation or other chemical effects can occur. Chemically matching the QDs to the organic host material and controlling the speed of “cure” are believed to be affect quantum efficiency. In certain embodiments, QDs are dispersed in organic host materials such as polymethylmethacrylate (PMMA) and polysiloxanes. For other quantum dot materials and hosts that may be useful with the present invention, see also Lee, et al., “Full Color Emission From II-VI Semiconductor Quantum-Dot Polymer Composites”. Adv. Mater. 2000, 12, No. 15 August 2, pp. 1102-1105, the disclosure of which is hereby incorporated herein by reference.

In certain embodiments, a QDLS in accordance with the invention includes two or more films of QDs embedded in a host chemically bonded to a PMMA waveguide. In certain embodiments, the two or more films cannot be separated by mechanical means. In certain embodiments, a waveguide including an amount QDs (including a core comprising a cadmium containing semiconductor) per area effective to achieve about 80-90% absorption in the waveguide, includes less than 100 ppm Cd. In certain embodiments, the quantum dots will comprise Cd-based QD materials. In certain embodiments, quantum dots will comprise Cd-free QD materials.

In certain embodiments, a QD-LEF comprises multi-layer stack of multi-wavelength QD-LEFs. In certain embodiments, a QD-LEF comprises multiplexed multi-wavelength QD-LEFs or spatially dithered QD-LEFs. The first approach includes two or more QD films, ordered from the lowest energy QD film directly on the waveguide to the highest energy QD film followed by a diffuser film at the air interface. This structure allows light that is down converted closer to the waveguide to travel unimpeded through subsequent layers, eventually to be out-coupled. In higher energy outer films, the photons emitted that travel back into the waveguide can be recycled by lower energy QDs. In all, though the downconversion efficiency will suffer from minor reabsorption losses, this loss will be most dependent on the QY of the films, which, at 80% QY, will be limited. The second approach, including spatially dithered multi-color QD inks, will also greatly alleviate reabsorption issues. This design separates each QD ink into discrete patterns on the waveguide, maintaining a very high absorption path for blue excitation light while providing a very small absorption path for internally directed down-converted photons. Though waveguided light from the QDs will see this large absorption path as well, the design of the luminaire greatly limits the percentage of QD down-converted photons that can enter a waveguide mode. Both film designs are expected to yield higher down-conversion efficiencies than mixed QD films and encapsulants. In addition, the density, size or concentration of QDs in the dithered pattern features can vary as a function of distance on the QD-LEF, in order to vary the spatial light output from the LEF in terms of luminance or color, or alternatively, to keep these characteristics uniform across the LEF.

In certain embodiments, LEDs will be optically coupled to the edge of the waveguide or diffuser. In certain embodiments, an LED comprises one of Luminus Devices' high power blue Phlatlight LEDs that have been optimized for edge coupling to a flat diffuser. The narrow emission cone of PhlatLight LED technology enables achievement of high LED-diffuser coupling efficiencies ranging 60-75%. Blue PhlatLight LEDs also exhibit very high power densities (200-300 mW/mm²) allowing use of very few LEDs to make a high lumen light sheet thereby reducing lamp module cost.

In certain embodiments, an LED and driver assembly will have an LED wall plug efficiency of at least 20% and more preferably, at least 30%.

In certain embodiments, an LED and driver assembly will have an LED output power density of at least 0.21 W/mm^{2,} and preferably, greater than 0.31 W/mm².

In certain embodiments, an LED will have an LED Output Power [W] of about 3.

In certain embodiments, an LED will have a peak wavelength of 450 nm.

In certain embodiments, an LED will have a FWHM of 20 nm or less.

In certain embodiments, an LED driver assembly will have a driver efficiency of at least 85% and more preferably at least 90%.

Most preferably, an LED comprises a Phlatlight available from Luminus Devices.

In certain embodiments including a diffuser, the LED coupling efficiency will be at least 60%, and more preferably, at least 75%.

In certain embodiments including a diffuser, the diffuser will have a diffuser transmission efficiency of at least 70%, and preferably, at least 80%.

In certain embodiments, the QD light enhancement film will have a down conversion efficiency of at least 60%, and preferably, at least 70%.

In certain embodiments of a QDLS, the luminous efficacy of radiation (lumens/watt) will be at least about 330, and preferably at least about 400.

In certain embodiments of a QDLS in accordance with the invention, the total lumen output will be at least 294, and preferably, at least 504.

In certain embodiments of a QDLS in accordance with the invention, the luminaire efficiency will be at least 42%, and preferably, at least 60%.

In certain embodiments of a QDLS in accordance with the invention, the total system efficacy (lm/W) will be at least 17, and preferably, at least 50.

In certain embodiments of a QDLS in accordance with the invention, the QDLS is capable of producing light with a CRI of at least 85%, and more preferably, at least 90%.

In certain embodiments of a QDLS in accordance with the invention, the QDLS is capable of producing light with a color temperature (CCT) of 5500K.

Examples of dimensions of one embodiment of a QDLS include, without limitation, an area of 10 cm×30 cm and a thickness of 10 mm.

In certain embodiments, simulating luminaire efficacy and CRI of a white light emitter can include different QDs to provide a plurality of distinctly different peak emission wavelengths. A full-width-at-half-maximum (FWHM) of 35 nm for the QD emission spectra in combination with the LED blue spectrum to simulate the spectrum will maximize CRI. It is expected that the highest CRI will be achieved with 4 or more specifically tuned QD emission spectra in the region of blue-green, green, yellow, and red corresponding to wavelengths in the range of 495, 540, 585, and 630 nm. In certain embodiments, core QD materials are synthesized using Cd-based QD material systems, which include CdSe, CdZnSe, and CdZnS. These core semiconductor materials allow for optimized size distribution, surface quality, and color tuning in the visible spectrum. For example, CdZnS can be fine tuned across the entire blue region of the visible spectrum, typically from wavelengths of 400-500 nm. CdZnSe cores can provide narrow band wavelengths of emission from 500-550 nm and CdSe is used to make the most efficient and narrow band emission in the yellow to deep red part of the visible spectrum (550-650). Each semiconductor material is selected to address the wavelength region of interest to optimize the physical size of the QD material, which is important in order to achieve good size distributions, high stability and efficiency, and trouble-free processability. In certain embodiments, for example, the use of a ternary semiconductor alloy also permits use of a ratio of cadmium to zinc in addition to the physical size of the core QD to tune the color of emission.

In certain embodiments, a semiconductor shell material comprises ZnS due to its large band gap leading to maximum exciton confinement in Cd-based core materials. The lattice mismatch between CdSe and ZnS is roughly 12%. The presence of Zn doped into the CdSe will decrease this mismatch to some degree, while the lattice mismatch between CdZnS and ZnS is minimal. In order to grow highly uniform and thick shells (e.g., 2 or more monolayers) onto CdSe cores for maximum particle stability and efficiency, a small amount of Cd is doped into the ZnS growth to create a CdZnS shell that is somewhat graded. In certain embodiments Cd is doped into the Zn and S precursors during initial shell growth in decreasing amounts to provide a truly graded shell, rich in Cd at the beginning fading to 100% ZnS at the end of the growth phase. This grading from CdSe core to CdS to CdZnS to ZnS will alleviate even more strain potentially allowing for even greater stability and efficiency for solid state lighting applications.

In certain embodiments, a quantum dot light sheet down-converts blue light from the source LEDs to a high CRI white. In certain embodiments, printed layers of quantum dot films will be deposited on top of a commercially-available molded light guide.

Light guides with suitably molded light extraction features are commonly used in display backlighting applications, and examples that are available commercially include molded light guiding plates made by Global Lighting Technologies, Inc. (http://www.glthome.com/). The key technology behind these light guides is the creation of “micro-lenses” on the backside of the waveguide, which couple a portion of the waveguided light out to the viewer. These features can be varied in spatial density in order to achieve 2D light extraction uniformity. In one embodiment, on the top side of these light guides, quantum dots contained within a polymer host matrix in order to perform the down conversion of the blue light with high CRI will be coated. The polymer host will be chosen based on its optical properties, processability, and compatibility with the quantum dots. Preferably chemically compatible quantum dots will aid in their dispersion and maintain their quantum efficiency in various host matrices.

In certain embodiments, a QD film may further include scattering particles, such as 0.2 □m TiO₂, in order to increase the path length of the blue excitation light in the film resulting in increased light emission and minimized concentration of quantum dots. For additional information, see also U.S. Patent Application No. 60/9493,06, filed 12 Jul. 2007, the disclosure of which is hereby incorporated herein by reference in its entirety.

In certain embodiments, a QD light enhancement film comprises the two or more individual QD layers uniformly layered on top of one another with low energy conversion layers below higher energy layers to minimize re-absorption.

In certain embodiments, a QD light enhancement film comprises individual QD/host compositions deposited side by side in a pixellated fashion, resulting in a composite white. This approach has the potential for a higher outcoupling efficiency and even lower re-absorption.

Both approaches are inherently low-cost as both can use high-volume, solution-based deposition techniques. Deposition methods including, but not limited to, slot or gravure coating directly on the waveguide or on a web that is then laminated to the waveguide are suitable for use in the layered approach. For the pixellated approach, screen printing is the simplest solution, with 50 um features easily achievable.

LED technology is considered to have great potential for solid state lighting (SSL). By themselves, however, LED light sources provide pure light of a particular wavelength corresponding to the band gap of the LED junction materials, resulting in light of poor CRI, and are therefore not suitable for SSL. In order to achieve a high CRI diffuse white lighting solution, multiple color LEDs are combined or phosphor materials are used to convert the LED source light into white light. Unfortunately, different LEDs have different temperature dependencies and lifetime characteristics, and phosphors are not available in a large enough variety to convert a LED light source into a color rendering index of excellent quality, nor would a combination of different phosphors share the same stability, including lifetime considerations as well as temperature stability. Phosphors are also scattering agents, and thus fine color tuning is greatly complicated, and their application in tandem with waveguiding is severely limited.

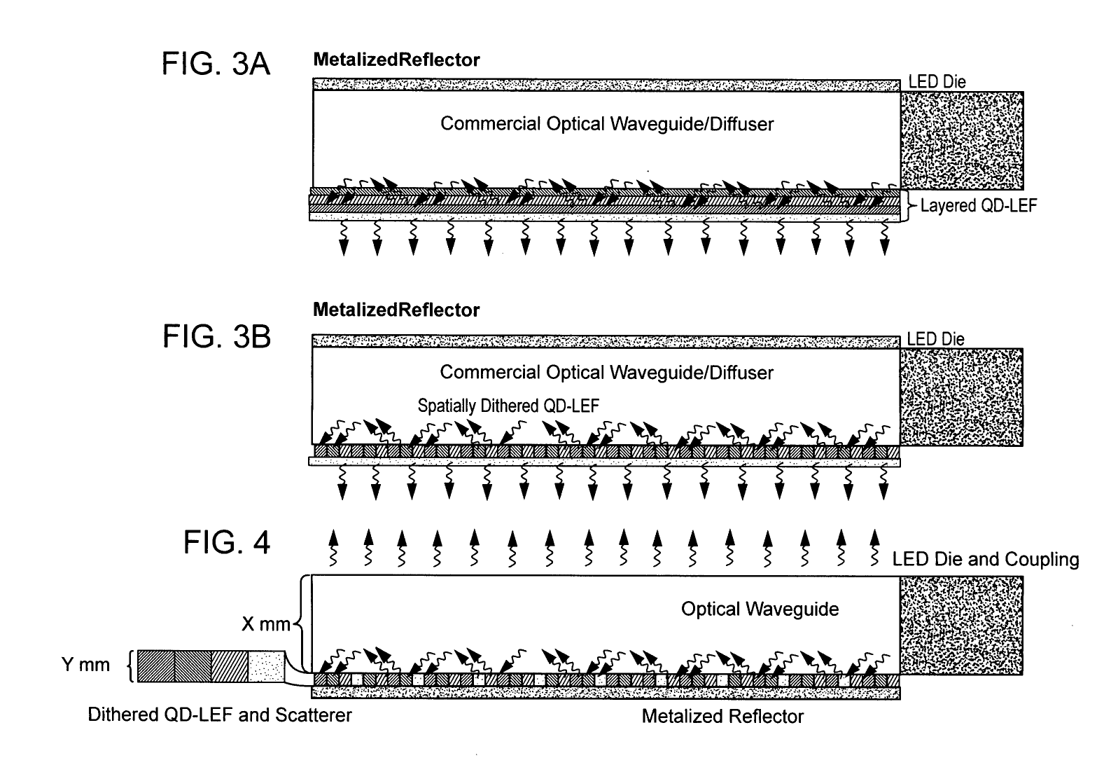

In accordance with certain embodiments of the present invention, QD-LEFs are included in luminaire devices to provide simple and more effective means of converting LED light into diffuse light (e.g., not point of light), having a CRI>85. The QD-LEF coupled luminaire can emit light of CRI, e.g., >85, by a down-conversion method either in conjunction with a uniform waveguiding diffuser (an example of an embodiment of which is schematically shown in FIG. 3) or will provide the uniform diffusive light out-coupling with an optical waveguide plate (an example of an embodiment of which is schematically shown in FIG. 4). In the example shown in FIG. 3, the QD-LEF waveguided light is partially down-converted by QDs in a probabilistic manner before being out coupled. As shown in the example illustrated in FIG. 3, an additional scattering layer or diffuser can be added if desired to further outcouple waveguided modes in the QD-LEF. Additional reflectors (not shown) can be added on the far edge and other sides of the waveguide to enhance outcoupling through the QD film side of the luminaire. (In the example shown in FIG. 3(a), the down-conversion layer closest to the substrate comprises a red-emitting material; a yellow-emitting is disposed over the red-emitting material; a green emitting material is disposed over the yellow-emitting material, and an outcoulping or protective layer is disposed over the green-emitting material.),

In both examples of configurations shown in FIG. 3 light is emitted by an LED die and coupled into a waveguide and/or diffuser. As this light propagates it is selectively down-converted by QD-LEFs, then fractionally scattered out of the luminaire diffusely. The depicted example of configuration (a) illustrates a layered approach, where lower energy films are coupled closer to the waveguide than higher energy films to minimize re-absorption effects, which tend to decrease down-conversion efficiencies. The depicted example of configuration (b) is a spatially-dithered approach, in which re-absorption is further limited by patterning the QD-LEFs across the surface. Both approaches can take into account the lateral wave-guiding effects which may manifest spatial down-conversion dependence, a phenomenon which will be addressed by film variations across the waveguide. The dithering approach lends itself particularly well to addressing this effect. (In the dithered example shown in FIG. 3(b), the arrangement includes a pattern of green, red, and yellow. In the dithered example shown in FIG. 4, the arrangement includes a pattern of green, red, yellow, and scatterers or nonscattering material.).

The examples of the embodiments of the QD-LEF applications shown in FIG. 3 can include commercial waveguides of a design which themselves provide spatial uniformity that will not be affected by the application of an index-matching QD-LEF. In the example of the embodiments of an alternative configuration shown in FIG. 4, the QD-LEF is applied to the back of a substantially lossless waveguide, providing red, yellow, and green light from their respective dithered patterning, and blue light from a dithered scattering pattern. In this application QDs are uniquely well suited in that they themselves do not scatter light, non-absorbed light continues unimpeded past quantum dots, while down-converted photons are emitted uniformly, making spatial dependences and CRI easily controlled.

Dithering or spatial dithering is a term used, for example, in digital imaging to describe the use of small areas of a predetermined palette of colors to give the illusion of color depth. For example, white is often created from a mixture of small red, green and blue areas. In certain embodiments, using dithering of compositions including different types of quantum dots (wherein each type is capable of emitting light of a different color) disposed on and/or embedded in a surface of a waveguide component can create the illusion of a different color. In certain embodiments, a waveguide and/or diffuser that appears to emit white light can be created from a dithered pattern of features including, for example, red, green and blue-emitting quantum dots. Dithered color patterns are well known. In certain embodiments, the blue light component of the white light can comprise outcoupled unaltered blue excitation light and/or excitation light that has been down-converted by quantum dots included in the waveguide component, wherein the quantum dots comprise a composition and size preselected to down-convert the excitation light to blue.

In certain embodiments, white light Can be obtained by layering films including different types of quantum dots (based on composition and size) wherein each type is selected to obtain light having a predetermined color.

In certain embodiments, white light can be obtained by including different types of quantum dots (based on composition and size) in a host material, wherein each type is selected to obtain light having a predetermined color.

FIG. 4 provides a schematic illustration of an example of a QD-LEF in a back-coupling application. Additional reflectors (not shown) can be added on the far edge and other sides of the waveguide to enhance outcoupling through the emitting face. In certain embodiments, the QD-LEF in the example depicted in FIG. 4 can also be positioned on the opposite side of the waveguide away from the reflector. Other QD-based outcoupling schemes can be utilized.

LED Luminaires employing QD-LEFs can exhibit high CRI light with tunable color temperature which is stable over the lifetime of the LED. This is the result of immeasurably stable QDs (100±5% of initial brightness after 10,000 hours and still under test) combined in a geometry such that the resultant light is uniquely independent of intensity and thus lifetime issues. As light is coupled into the QD-LEFs, photons will have a probability of being absorbed and re-emitted which, by definition, makes the light output independent of photon flux, resulting in an additional independence from source dimming.

In certain embodiments, a QDLS in accordance with the invention will include QD materials for emission at the 4 or more predetermined or specified wavelengths. Table 1 below summarizes examples of QD material performance specifications and core/shell materials to achieve the QDLS spectrum shown in FIG. 2 giving a CRI=96. Preferably core-shell QD materials will be utilized to emit at 4 or more predetermined wavelengths. More preferably, core-shell semiconductor nanocrystals will be utilized to emit at 4 or more predetermined wavelengths.

In certain embodiments a core QDs (comprising, for example, but not limited to, CdSe, CdZnSe, or CdZnS) will be synthesized at the desired wavelengths of emission with narrow size distributions and high surface quality. Next, a shell material, preferably an alloy shell materials (e.g., CdZnS) will be grown over at least a portion of a surface (preferably substantially all) of the core QDs in order to provide the greatest core surface passivation for high QYs and stability. Preferably at least a portion of the quantum dots include one or more surface capping ligands on a surface thereof that demonstrate chemical compatibility between QD emitters and any materials with which the QDs will be used or included.

TABLE 1
Exemplary QD performance targets for QDLS spectrum shown in FIG. 2.

| | Most Preferred | | | | |
|---|---|---|---|---|---|
| | Peak Wavelength | Preferred FWHM | Preferred | Most Preferred | |
| Color | (nm) | (nm) | QY | QY | Core/Shell |
| Blue- | 495 | No greater than 35 | At least 60% | At least 80% | CdZnS/ZnS |
| Green | | | | | |
| Green | 540 | No greater than 35 | At least 65% | At least 80% | CdZnSe/CdZnS |
| Orange | 585 | No greater than 35 | At least 65% | At least 80% | CdSe/CdZnS |
| Red | 630 | No greater than 35 | At least 75% | At least 80% | CdSe/CdZnS |

In certain embodiments, a layer or film including quantum dots may further include an organic or an inorganic host materials suitable for integration with off-the-shelf diffusers. Examples of components that may be included in a film or layer coating composition include, without limitation, quantum dots, monomers, prepolymers, initiators, scattering particles, and other additives necessary for screen printing. Preferably, a layer or film is deposited using a gelling protocol that minimizes heat exposure to dots, as well as a deposition approach capable of multiple layer and patterned QD-LEFs.

In certain preferred embodiments, a QDLS will include LED-diffuser coupling techniques that minimize insertion losses between the LED luminaire and diffuser as well as the diffuser and QD-LEF, with special emphasis on reabsorption mitigation.

In certain embodiments, the QDLS component interactions, including improving LED-diffuser and QD-LEF-diffuser coupling optics in conjunction with reabsorption minimization are optimized to realize maximum module efficiency and CRI versus current and lifetime as well as reduced module cost.

In certain embodiments, a quantum dot light sheet luminaire product is projected to have a total system efficacy of at least 50 lm/W.

The availability of high efficiency light sources has not always lead to the large scale adoption of such sources in commercial, and especially residential, environments. This is in part because light sources such as fluorescent lighting were inferior in many human- and form-based requirements. Low CRI, flicker, and shadowing all limit adoption of efficient technologies if they are not best-in-class, and hence limit environmental impact of certain technologies.

In addition, advancement in environment-friendly technology and material efficient processing methods will contribute to economic benefits such as reduction in power consumption, reduction of green house gases leading to positive impact on climate, and reduction of hazardous waste.

Quantum dots (QDs), preferably semiconductor nanocrystals, permit the combination of the soluble nature and processability of polymers with the high efficiency and stability of inorganic semiconductors. QDs are more stable in the presence of water vapor and oxygen than their organic semiconductor counterparts. Because of their quantum-confined emissive properties, their luminescence is extremely narrow-band and yields highly saturated color emission, characterized by a single Gaussian spectrum. Finally, because the nanocrystal diameter controls the QD optical band gap, fine tuning of absorption and emission wavelength can be achieved through synthesis and structure changes, facilitating the process for identifying and optimizing luminescent properties. Colloidal suspensions of QDs (also referred to as solutions) can be prepared that: (a) emit anywhere across the visible and infrared spectrum; (b) are orders of magnitude more stable than organic lumophores in aqueous environments; (c) have narrow full-width half-maximum (FWHM) emission spectrum (e.g., below 50 nm, below 40 nm, below 30 nm, below 20 nm); and (d) have quantum yields up to greater than 85%.

A quantum dot is a nanometer sized particle, e.g., in the size range of up to about 1000 nm. In certain embodiments, a quantum dot can have a size in the range of up to about 100 nm. In certain embodiments, a quantum dot can have a size in the range up to about 20 nm (such as about 1, 2, 3, 4, 5, 6, 7, 8, 9, 10, 11, 12, 13, 14, 15, 16, 17, 18, 19, or 20 nm). In certain preferred embodiments, a quantum dot can have a size less than 100 Å. In certain preferred embodiments, a nanocrystal has a size in a range from about 1 to about 6 nanometers and more particularly from about 1 to about 5 nanometers. The size of a quantum dot can be determined, for example, by direct transmission electron microscope measurement. Other known techniques can also be used to determine nanocrystal size.

Quantum dots can have various shapes. Examples of the shape of a quantum dot include, but are not limited to, sphere, rod, disk, tetrapod, other shapes, and/or mixtures thereof.

In certain preferred embodiments, QDs comprise inorganic semiconductor material which permits the combination of the soluble nature and processability of polymers with the high efficiency and stability of inorganic semiconductors. Inorganic semiconductor QDs are typically more stable in the presence of water vapor and oxygen than their organic semiconductor counterparts. Because of their quantum-confined emissive properties, their luminescence can be extremely narrow-band and can yield highly saturated color emission, characterized by a single Gaussian spectrum. Finally, because the nanocrystal diameter controls the QD optical band gap, the fine tuning of absorption and emission wavelength can be achieved through synthesis and structure change.

In certain embodiments, inorganic semiconductor nanocrystal quantum dots comprise Group IV elements, Group II-VI compounds, Group II-V compounds, Group III-VI compounds, Group III-V compounds, Group IV-VI compounds, Group I-III-VI compounds, Group II-IV-VI compounds, or Group II-IV-V compounds, alloys thereof and/or mixtures thereof, including ternary and quaternary alloys and/or mixtures. Examples include, but are not limited to, ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbO, PbS, PbSe, PbTe, alloys thereof, and/or mixtures thereof, including ternary and quaternary alloys and/or mixtures.

As discussed herein, in certain embodiments a quantum dot can include a shell over at least a portion of a surface of the quantum dot. This structure is referred to as a core-shell structure. Preferably the shell comprises an inorganic material, more preferably an inorganic semiconductor material, An inorganic shell can passivate surface electronic states to a far greater extent than organic capping groups. Examples of inorganic semiconductor materials for use in a shell include, but are not limited to, Group IV elements, Group II-VI compounds, Group II-V compounds, Group III-VI compounds, Group III-V compounds, Group IV-VI compounds, Group compounds, Group II-IV-VI compounds, or Group II-IV-V compounds, alloys thereof and/or mixtures thereof, including ternary and quaternary alloys and/or mixtures. Examples include, but are not limited to, ZnO, ZnS, ZnSe, ZnTe, CdO, CdS, CdSe, CdTe, HgO, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbO, PbS, PbSe, PbTe, alloys thereof, and/or mixtures thereof, including ternary and quaternary alloys and/or mixtures.

The most developed and characterized QD materials to date are II-VI semiconductors, including CdSe, CdS, and CdTe. CdSe, with a bulk band gap of 1.73 eV (716 nm) (C. B. Murray, D. J. Norris, M. G. Bawendi, J. Am. Chem. Soc. 1993, 115, 8706.), can be made to emit across the entire visible spectrum with narrow size distributions and high emission quantum efficiencies. For example, roughly 2 nm diameter CdSe QDs emit in the blue while 8 nm diameter particles emit in the red. Changing the QD composition by substituting other semiconductor materials with a different band gap into the synthesis alters the region of the electromagnetic spectrum in which the QD emission can be tuned. For example, the smaller band gap semiconductor CdTe (1.5 eV, 827 nm) (C. B. Murray, D. J. Norris, M. G. Bawendi, J. Am. Chem. Soc. 1993, 115, 8706) can access deeper red colors than CdSe. Another QD material system includes lead containing semiconductors (e.g., PbSe and PbS). For example, PbS with a band gap of 0.41 eV (3027 nm) can be tuned to emit from 800 to 1800 nm (M. A. Hines, G. D. Scholes, Adv. Mater. 2003, 15, 1844.). It is theoretically possible to design an efficient and stable inorganic QD emitter that can be synthesized to emit at any desired wavelength from the UV to the NIR.

Semiconductor QDs grown in the presence of high-boiling organic molecules, referred to as colloidal QDs, yield high quality nanoparticles that are well-suited for light-emission applications. For example, the synthesis includes the rapid injection of molecular precursors into a hot solvent (300-360° C.), which results in a burst of homogeneous nucleation. The depletion of the reagents through nucleation and the sudden temperature drop due to the introduction of the room temperature solution of reagents minimizes further nucleation. This technique was first demonstrated by Murray and co-workers (C. B. Murray, D. J. Norris, M. G. Bawendi, J. Am. Chem. Soc. 1993, 115, 8706) for the synthesis of II-VI semiconductor QDs by high-temperature pyrolysis of organometallic precursors (dimethylcadmium) in coordinating solvents (tri-n-octylphosphine (TOP) and tri-n-octylphosphine oxide (TOPO)). This work was based on the seminal colloidal work by LaMer and Dinegar (V. K. LaMer, R. H. Dinegar, J. Am. Chem. Soc. 1950, 72, 4847.), who introduced the idea that lyophobic colloids grow in solution via a temporally discrete nucleation event followed by controlled growth on the existing nuclei.

The ability to control and separate the nucleation and growth environments is in large part provided by selecting the appropriate high-boiling organic molecules used in the reaction mixture during the QD synthesis. The high-boiling solvents are typically organic molecules made up of a functional head including, for example, a nitrogen, phosphorous, or oxygen atom, and a long hydrocarbon chain. The functional head of the molecules attach to the QD surface as a monolayer or multilayer through covalent, dative, or ionic bonds and are referred to as capping groups. The capping molecules present a steric barrier to the addition of material to the surface of a growing crystallite, significantly slowing the growth kinetics. It is desirable to have enough capping molecules present to prevent uncontrolled nucleation and growth, but not so much that growth is completely suppressed.

This colloidal synthetic procedure for the preparation of semiconductor QDs provides a great deal of control and as a result the synthesis can be optimized to give the desired peak wavelength of emission as well as a narrow size distribution. This degree of control is based on the ability to change the temperature of injection, the growth time, as well as the composition of the growth solution. By changing one or more of these parameters the size of the QDs can be engineered across a large spectral range while maintaining good size distributions.

Semiconductor QDs such as CdSe are covalently bonded solids with four bonds per atom, which have been shown to retain the bulk crystal structure and lattice parameters (M. G. Bawendi, A. R. Kortan, M. L. Steigerwald, L. E. Brus, J. Chem. Phys. 1989, 91, 7282). At the surface of a crystal, the outermost atoms do not have neighbors which they can bond to, generating surface states of different energy levels that lie within the band gap of the semiconductor. Surface rearrangements take place during crystal formation to minimize the energy of these surface atoms, but because such a large percentage of the atoms that make up a QD are on the surface (>75% to <0.5% for QDs <1 nm to >20 nm in diameter, respectively) (C. B. Murray, C. R. Kagan, M. G. Bawendi, Annu. Rev. Mater. Sci. 2000, 30, 545), the effect on the emission properties of semiconductor QDs is quite large. The surface states lead to non-radiative relaxation pathways, and thus a reduction in the emission efficiency or quantum yield (QY).

When molecules are chemically bound to the surface of a QD, they help to satisfy the bonding requirements of the surface atoms, eliminating many of the surface states and corresponding non-radiative relaxation pathways. This results in QDs with good surface passivation and higher QY as well as higher stability than QDs with poor surface passivation. Thus, design and control of the growth solution and processing can achieve good passivation of the surface states and results in high QYs. Furthermore, these capping groups can play a role in the synthetic process as well by mediating particle growth and sterically stabilizing the QDs in solution.

The most effective method for creating QDs with high emission efficiency and stability is to grow an inorganic semiconductor shell onto QD cores. A core-shell type composite rather than organically passivated QDs is desirable for incorporation into solid-state structures, such as a solid state QD-LED device, due to their enhanced photoluminescence (PL) and electroluminescence (EL) quantum efficiencies and a greater tolerance to the processing conditions necessary for device fabrication (B. O. Dabbousi, J. Rodriguez-Viejo, F. V. Mikulec, J. R. Heine, H. Mattoussi, R. Ober, K. F. Jensen, M. G. Bawendi, J. Phys. Chem. B 1997, 101, 9463; B. O. Dabbousi, O. Onitsuka, M. G. Bawendi, M. F. Rubner, Appl. Phys. Lett. 1995, 66, 1316; M. A. Hines, P. Guyot-Sionnest, J. Phys. Chem. 1996, 100, 468; S. Coe-Sullivan, W. K. Woo, J. S. Steckel, M. G. Bawendi, V. Bulović, Org. Electron. 2003, 4, 123. When a shell of a larger band gap material is grown onto a core QD, for example ZnS (band gap of 3.7 eV) onto CdSe, the majority of the surface electronic states are passivated and a 2 to 4 fold increase in QY is observed (B. O. Dabbousi, J. Rodriguez-Viejo, F. V. Mikulec, J. R. Heine, H. Mattoussi, R. Ober, K. F. Jensen, M. G. Bawendi, J. Phys. Chem. B 1997, 101, 9463). The presence of a shell of a different semiconductor (in particular one that is more resistant to oxidation) on the core also protects the core from degradation.

Due to the superior properties of core-shell materials outlined above, it is desirable to focus on such a system when designing new QD material systems. Consequently, one factor in QD core-shell development is the crystal structure of the core and shell material as well as the lattice parameter mismatch between the two. The lattice mismatch between CdSe and ZnS is 12% (B. O. Dabbousi, J. Rodriguez-Viejo, F. V. Mikulec, J. R. Heine, H. Mattoussi, R. Ober, K. F. Jensen, M. G. Bawendi, J. Phys. Chem. B 1997, 101, 9463), which is considerable, but because only a few atomic layers (e.g., from 1 to 6 monolayers) of ZnS are grown onto CdSe the lattice strain is tolerated. The lattice strain between the core and shell materials scales with the thickness of the shell. As a result, a shell that is too thick can cause dislocations at the material interface and will eventually break off of the core. Doping a shell (e.g., ZnS shell with Cd) can relieve some of this strain, and as a result thicker shells (in this example, CdZnS) can be grown. The effect is similar to transitioning more gradually from CdSe to CdS to ZnS (the lattice mismatch between CdSe and CdS is about 4% and that between CdS and ZnS about 8%), which provides for more uniform and thicker shells and therefore better QD core surface passivation and higher quantum efficiencies.

While core-shell particles exhibit improved properties compared to core-only systems, good surface passivation with organic ligands is still desirable for maintaining quantum efficiency of core-shell QDs. This is due to the fact that the particles are smaller than the exciton Bohr radius, and as a result the confined excited-state wavefunction has some probability of residing on the surface of the particle even in a core-shell type composite. Strong binding ligands that passivate the surface improve the stability and efficiency of core-shell QD material.

One example of a method for synthesizing quantum dots includes a colloidal synthesis techniques as described above, typically exhibit highly saturated color emission with narrow full-width-at-half-maximums (FWHM), preferably less than 30 nm. The number of accessible emission colors is virtually unlimited, due to the fact that the QD peak emission can be tailored by selecting the appropriate material system and size of the nanoparticles. Colloidally synthesized red, green and blue Cd-based QDs can routinely achieve solution quantum yields on the order of 70-80%, with peak emission wavelength reproducibility within +/−2% and FWHM less than 30 nm.

In certain embodiments, QDs include a core comprising InP. Preferably such QDs have a 50% solution quantum yields or higher. In certain embodiments, such QDs are prepared by a colloidal synthesis process. An example of a process for preparing QDs including a core comprising InP or other III-V semiconductor materials is described in U.S. Patent Application No. 60/866,822 of Clough, et al., filed 21 Nov. 2006, the disclosure of which is hereby incorporated herein by reference in its entirety).

Quantum dots included in various aspects and embodiments of the inventions contemplated by this disclosure are preferably members of a population of quantum dots having a narrow size distribution. More preferably, the quantum dots comprise a monodisperse or substantially monodisperse population of quantum confined semiconductor nanoparticles.

Examples of other quantum dots materials and methods that may be useful with the present invention include those described in: International Application No. PCT/US2007/13152, entitled “Light-Emitting Devices And Displays With Improved Performance”, of Seth Coe-Sullivan, et al., filed 4 Jun. 2007, U.S. Provisional Patent Application No. 60/866,826, filed 21 Nov. 2006, entitled “Blue Light Emitting Semiconductor Nanocrystal Materials And Compositions And Devices Including Same”, of Craig Breen et al.; U.S. Provisional Patent Application No. 60/866,828, filed 21 Nov. 2006, entitled “Semiconductor Nanocrystal Materials And Compositions And Devices Including Same”, of Craig Breen et al.; U.S. Provisional Patent Application No. 60/866,832, filed 21 Nov. 2006, entitled “Semiconductor Nanocrystal Materials And Compositions And Devices Including Same”, of Craig Breen et al.; U.S. Provisional Patent Application No. 60/866,833, filed 21 Nov. 2006, entitiled “Semiconductor Nanocrystal And Compositions And Devices Including Same”, of Dorai Ramprasad; U.S. Provisional Patent Application No. 60/866,834, filed 21 Nov. 2006, entitiled “Semiconductor Nanocrystal And Compositions And Devices Including Same”, of Dorai Ramprasad; U.S. Provisional Patent Application No. 60/866,839, filed 21 Nov. 2006, entitiled “Semiconductor Nanocrystal And Compositions And Devices Including Same”, of Dorai Ramprasad; U.S. Provisional Patent Application No. 60/866,840, filed 21 Nov. 2006, entitiled “Blue Light Emitting Semiconductor Nanocrystal And Compositions And Devices Including Same”, of Dorai Ramprasad; and U.S. Provisional Patent Application No. 60/866,843, filed 21 Nov. 2006, entitiled “Semiconductor Nanocrystal And Compositions And Devices Including Same”, of Dorai Ramprasad. The disclosures of each of foregoing listed patent applications are hereby incorporated herein by reference in their entireties.

An example of a deposition technology that may be useful in applying quantum dot materials and films or layers including quantum dot materials to a surface that may be useful with the present invention includes microcontact printing.

QD materials and films or layers including QD materials can be applied to flexible or rigid substrates by microcontact printing, inkjet printing, etc. The combined ability to print colloidal suspensions of QDs over large areas and to tune their color over the entire visible spectrum makes them an ideal lumophore for solid-state lighting applications that demand tailored color in a thin, light-weight package. QDs and films or layer including QDs can be applied to a surface by various deposition techniques. Examples include, but are not limited to, those described in International Patent Application No. PCT/US2007/08873, entitled “Composition Including Material, Methods Of Depositing Material, Articles Including Same And Systems For Depositing Material”, of Seth A. Coe-Sullivan, et al., filed 9 Apr. 2007, International Patent Application No. PCT/US2007/09255, entitled “Methods Of Depositing Material, Methods Of Making A Device, And Systems And Articles For Use In Depositing Material”, of Maria J, Anc, et al., filed 13 Apr. 2007, International Patent Application No. PCT/US2007/08705, entitled “Methods And Articles Including Nanomaterial”, of Seth Coe-Sullivan, et al, filed 9 Apr. 2007, International Patent Application No. PCT/US2007/08721, entitled “Methods Of Depositing Nanomaterial & Methods Of Making A Device” of Marshall Cox, et al., filed 9 Apr. 2007, U.S. patent application Ser. No. 11/253,612, entitled “Method And System For Transferring A Patterned Material” of Seth Coe-Sullivan, et al., filed 20 Oct. 2005, U.S. patent application Ser. No. 11/253,595, entitled “Light Emitting Device Including Semiconductor Nanocrystals”, of Seth Coe-Sullivan, et al., filed 20 Oct. 2005, International Patent Application No. PCT/US2007/14711, entitled “Methods for Depositing Nanomaterial, Methods For Fabricating A Device, And Methods For Fabricating An Array Of Devices”, of Seth Coe-Sullivan, filed 25 Jun. 2007, International Patent Application No. PCT/US2007/14705, “Methods for Depositing Nanomaterial, Methods For Fabricating A Device, And Methods For Fabricating An Array Of Devices And Compositions”, of Seth Coe-Sullivan, et al., filed 25 Jun. 2007, and International Application No. PCT/US2007/14706, entitled “Methods And Articles Including Nanomaterial”, of Seth Coe-Sullivan, et al., filed 25 Jun. 2007. Each of the foregoing patent applications is hereby incorporated herein by reference in its entirety.

Additional information concerning quantum dot materials, various methods including quantum dots, and devices including quantum dot materials is includes in the following publications are hereby incorporated herein by reference in their entireties: P. Kazlas, J. Steckel, M. Cox, C. Roush, D. Ramprasad, C. Breen, M. Misic, V. DiFilippo, M. Anc, J. Ritter and S. Coe-Sullivan “Progress in Developing High Efficiency Quantum Dot Displays” SID '07 Digest, P176 (2007); G. Moeller and S. Coe-Sullivan “Quantum-Dot Light-Emitting Devices for Displays” SID '06 Digest (2006); J. S. Steckel, B. K. H. Yen, D. C. Oertel, M. G. Bawendi, “On the Mechanism of Lead Chalcogenide Nanocrystal Formation”, Journal of the American Chemical Society, 128, 13032 (2006); J. S. Steckel, P. Snee, S. Coe-Sullivan, J. P. Zimmer, J. E. Halpert, P. Anikeeva, L. Kim, M. G. Bawendi, and V. Bulovic, “Color Saturated Green-Emitting QD-LEDs”, Angewandte Chemie International Edition, 45, 5796 (2006); P. O. Anineeva, C. F. Madigan, S. A. Coe-Sullivan, J. S. Steckel, M. G. Bawendi, and V. Bulović, “Photoluminescence of CdSe/ZnS Core/Shell Quantum Dots Enhanced by Energy Transfer from a Phosphorescent Donor,” Chemical Physics Letters, 424, 120 (2006); Y. Chan, J. S. Steckel, P. T. Snee, J.-Michel Caruge, J. M. Hodgkiss, D. G. Nocera, and M. G. Bawendi, “Blue semiconductor nanocrystal laser”, Applied Physics Letters, 86, 073102 (2005); S. Coe Sullivan, W. woo, M. G. Bawendi, V. Bulovic “Electroluminescence of Single Monolayer of Nanocrystals in Molecular Organic Devices”, Nature (London) 420, 800 (2002); S. Coe-Sullivan, J. S. Steckel, L. Kim, M. G. Bawendi, and V. Bulovic, “Method for fabrication of saturated RGB quantum dot light-emitting devices”, Proc. of SPIE Int. Soc. Opt. Eng., 108, 5739 (2005); J. S. Steckel, J. P. Zimmer, S. Coe-Sullivan, N. Stott, V. Bulović, M. G. Bawendi, “Blue Luminescence from (CdS)ZnS Core-Shell Nanocrystals”, Angewandte Chemie International Edition, 43, 2154 (2004); Y. Chan, J. P. Zimmer, M. Stroh, J. S. Steckel, R. K. Jain, M. G. Bawendi, “Incorporation of Luminescent Nanocrystals into Monodisperse Core-Shell Silica Microspheres”, Advanced Materials, 16, 2092 (2004); J. S. Steckel, N. S. Persky, C. R. Martinez, C. L. Barnes, E. A. Fry, J. Kulkarni, J. D. Burgess, R. B. Pacheco, and S. L. Stoll, “Monolayers and Multilayers of [Mn12O12(O2CMe)16]”, Nano Letters, 4, 399 (2004); Y. K. Olsson, G. Chen, R. Rapaport, D. T. Fuchs, and V. C. Sundar, J. S. Steckel, M. G. Bawendi, A. Aharoni, U. Banin, “Fabrication and optical properties of polymeric waveguides containing nanocrystalline quantum dots”, Applied Physics Letters, 18 4469 (2004); D. T. Fuchs, R. Rapaport, G. Chen, Y. K. Olsson, V. C. Sundar, L. Lucas, and S. Vilan, A. Aharoni and U. Banin, J. S. Steckel and M. G. Bawendi, “Making waveguides containing nanocrystalline quantum dots”, Proc. of SPIE, 5592, 265 (2004); J. S. Steckel, S. Coe-Sullivan, V. Bulović, M. G. Bawendi, “1.3 μm to 1.55 μm Tunable Electroluminescence from PbSe Quantum Dots Embedded within an Organic Device”, Adv. Mater., 15, 1862 (2003); S. Coe-Sullivan, W. Woo, J. S. Steckel, M. G. Bawendi, V. Bulović, “Tuning the Performance of Hybrid Organic/Inorganic Quantum Dot Light-Emitting Devices”, Organic Electronics, 4, 123 (2003); and the following patents of Robert F. Karlicek, Jr., U.S. Pat. Nos. 6,746,889 “Optoelectronic Device with Improved Light Extraction”; 6,777,719 “LED Reflector for Improved Light Extraction”; 6,787,435 “GaN LED with Solderable Backside Metal”; 6,799,864 “High Power LED Power Pack for Spot Module Illumination”; 6,851,831 “Close Packing LED Assembly with Versatile Interconnect Architecture”; 6,902,990 “Semiconductor Device Separation Using a Patterned Laser Projection”; 7,015,516 “LED Packages Having Improved Light Extraction”; 7,023,022 “Microelectronic Package Having Improved Light Extraction”; 7,170,100 “Packaging Designs for LEDs”; and 7,196,354 “Wavelength Converting Light Emitting Devices”.

Additional information relating to semiconductor nanocrystals and their use is also found in U.S. Patent Application No. 60/620,967, filed Oct. 22, 2004, and Ser. No. 11/032,163, filed Jan. 11, 2005, U.S. patent application Ser. No. 11/071,244, filed 4 Mar. 2005. Each of the foregoing patent applications is hereby incorporated herein by reference in its entirety.

As used herein, “top”, “bottom”, “over”, and “under” are relative positional terms, based upon a location from a reference point. More particularly, “top” means farthest away from a reference point, while “bottom” means closest to the reference point. Where, e.g., a layer is described as disposed or deposited “over” a component or substrate, the layer is disposed farther away from the component or substrate. There may be other layers between the layer and component or substrate. As used herein, “cover” is also a relative position term, based upon a location from a reference point. For example, where a first material is described as covering a second material, the first material is disposed over, but not necessarily in contact with the second material.

As used herein, the singular forms “a”, “an” and “the” include plural unless the context clearly dictates otherwise. Thus, for example, reference to a nanomaterial includes reference to one or more of such materials.

All the patents and publications mentioned above and throughout are incorporated in their entirety by reference herein. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)

61. (canceled)

62. (canceled)

63. (canceled)

64. (canceled)

65. (canceled)

66. (canceled)

67. (canceled)

68. (canceled)

69. (canceled)

70. (canceled)

71. (canceled)

72. (canceled)

73. (canceled)

74. (canceled)

75. (canceled)

76. (canceled)

77. (canceled)

78. (canceled)

79. (canceled)

80. (canceled)

81. (canceled)

82. (canceled)

83. (canceled)

84. (canceled)

85. (canceled)

86. (canceled)

87. (canceled)

88. (canceled)

89. (canceled)

90. (canceled)

91. (canceled)

92. (canceled)

93. (canceled)

94. (canceled)

95. (canceled)

96. (canceled)

97. (canceled)

98. (canceled)

99. (canceled)

100. (canceled)

101. (canceled)

102. (canceled)

103. (canceled)

104. A solid state lighting device including an optical component comprising an optically transparent substrate including a layer comprising a predetermined arrangement of features on a first surface of the substrate, wherein at least a first portion of the features comprise a down-conversion material comprising quantum dots and at least a second portion of the features comprise scatterers, and wherein a light source is optically coupled to the substrate.

105. (canceled)

106. (canceled)

107. (canceled)

108. (canceled)

109. (canceled)

110. (canceled)

111. A solid state lighting device comprising an optically transparent substrate including a layer comprising a predetermined arrangement of features on a first surface of the substrate, wherein at least a portion of the features comprise a down-conversion material comprising quantum dots and scatterers, the substrate being optically coupled to a light source.

112. A solid state lighting device in accordance with claim 111 further comprising a surface adapted for outcoupling light emitted from the optical component of the device.

113. (canceled)

114. A solid state lighting device in accordance with claim 111 wherein the light source is embedded in the substrate.

115. (canceled)

116. A solid state lighting device in accordance with claim 111 wherein the light source is optically coupled to the substrate through a prism.

117. (canceled)

118. (canceled)

119. A solid state lighting device in accordance with claim 111 wherein the predetermined arrangement further includes features comprising scatterers and/or nonscattering material without down-conversion material.

120. (canceled)

121. A solid state lighting device in accordance with claim 119 wherein nonscattering material comprises clear acrylic, UV curable adhesive, or polycarbonate.

122. (canceled)

123. A solid state lighting device in accordance with claim 112 wherein the surface includes microlenses for outcoupling light.

124. A solid state lighting device in accordance with claim 112 wherein the surface includes micro-relief structures for outcoupling light.

125. A solid state lighting device in accordance with claim 111 wherein the predetermined arrangement comprises a dithered arrangement including features including down-conversion material.

126. A solid state lighting device in accordance with claim 125 wherein at least a portion of the features are optically isolated from other features.

127. A solid state lighting device in accordance with claim 126 wherein at least a portion of the features are optically isolated from other features by air.

128. A solid state lighting device in accordance with claim 126 wherein at least a portion of the features are optically isolated from other features by a lower or higher refractive index material.

129. A solid state lighting device in accordance with claim 111 wherein the down-conversion material further comprises a binder in which the quantum dots are dispersed.

130. A solid state lighting device in accordance with claim 104 wherein the down-conversion material further comprises a solid host material.

131. (canceled)

132. A solid state lighting device in accordance with claim 130 wherein at least a portion of the features are configured to have predetermined outcoupling angles.

133. (canceled)

134. (canceled)

135. (canceled)

136. (canceled)

137. (canceled)

138. A solid state lighting device in accordance with claim 132 wherein the features include a substantially hemispherical surface.

139. A solid state lighting device in accordance with claim 132 wherein the features include a curved surface.

140. A solid state lighting device in accordance with claim 132 wherein the features comprise a prism geometry.

141. A solid state lighting device in accordance with claim 132 wherein the features are included in a dithered arrangement.

142. A solid state lighting device in accordance with claim 111 wherein the light source is optically coupled to an edge of the substrate.

143. A solid state lighting device in accordance with claim 142 wherein the number of features and closeness of features to each other increases as a function of increasing distance from the light source.

144. A solid state lighting device in accordance with claim 143 wherein the light emitted from the device is substantially uniform across a predetermined region of the substrate surface.

145. (canceled)

146. (canceled)

147. (canceled)

148. (canceled)

149. A solid state lighting device in accordance with claim 119 wherein at least a portion of features comprising down-conversion material include down-conversion material that is selected to include quantum dots capable converting the wavelength of at least a portion of a first portion of light emission from the light source to one or more predetermined wavelengths, and features without down-conversion material outcouple at least a portion of a second portion of light emission from the light source.

150. A solid state lighting device in accordance with claim 111 wherein the features are arranged in a dithered arrangement and wherein down-conversion material included in each of the features that include down-conversion material is selected to include quantum dots capable of converting at least a portion of light emission from the light source to one or more predetermined wavelengths such that the optical component is capable of emitting white light when optically coupled to the light source.

151. A solid state lighting device in accordance with claim 111 wherein the light source is a UV light source.

152. A solid state lighting device in accordance with claim 151 wherein the light source comprises an LED capable of emitting 405 nm light.

153. A solid state lighting device in accordance with claim 151 wherein features including down-conversion material include a first portion of the features that include quantum dots capable of emitting red light, a second portion of the features that include quantum dots capable of emitting green light, and a third portion of the features that include quantum dots capable of emitting blue light.

154. A solid state lighting device in accordance with claim 151 wherein features including down-conversion material include a first portion of the features that include quantum dots capable of emitting blue light, and a second portion of the features that include quantum dots capable of emitting yellow light.

155. A solid state lighting device in accordance with claim 151 wherein features including down-conversion material include a first portion of the features that include quantum dots capable of emitting blue light, a second portion of the features that include quantum dots capable of emitting green light, a third portion of the features that include quantum dots capable of emitting yellow light, and a fourth portion of the features that include quantum dots capable of emitting red light.

156. A solid state lighting device in accordance with claim 151 wherein features including down-conversion material include a first portion of the features that include quantum dots capable of emitting red light, a second portion of the features that include quantum dots capable of emitting orange light, a third portion of the features that include quantum dots capable of emitting yellow light, a fourth portion of the features that include quantum dots capable of emitting green light, and a fifth portion of the features that include quantum dots capable of emitting blue light.

157. A solid state lighting device in accordance with claim 119 wherein the light source is a blue-light emitting light source.

158. A solid state lighting device in accordance with claim 157 wherein the light source comprises an LED capable of emitting 450 or 470 nm light.

159. A solid state lighting device in accordance with claim 157 wherein features including down-conversion material include a first portion of the features that include quantum dots capable of emitting green light, a second portion of the features that include quantum dots capable of emitting yellow light, and a third portion of the features that include quantum dots capable of emitting red light.

160. A solid state lighting device in accordance with claim 157 wherein features including down-conversion material include quantum dots capable of emitting yellow light.

161. A solid state lighting device in accordance with claim 157 wherein features including down-conversion material include a first portion of the features that include quantum dots capable of emitting red light, a second portion of the features that include quantum dots capable of emitting orange light, a third portion of the features that include quantum dots capable of emitting yellow light, and a fourth portion of the features that include quantum dots capable of emitting green light.

162. A solid state lighting device in accordance with claim 157 wherein features including down-conversion material include a first portion of the features that include quantum dots capable of emitting red light, and a second portion of the features that include quantum dots capable of emitting green light.
